(19) United States
(12) Patent Application Publication
(10) Pub. No.: US 2023/0361138 A1
(43) Pub. Date: Nov. 9, 2023

(54) IMAGING DEVICE

(71) Applicant: Panasonic Intellectual Property Management Co., Ltd., Osaka (JP)

(72) Inventor: KOSAKU SAEKI, Hyogo (JP)

(21) Appl. No.: 18/353,942

(22) Filed: Jul. 18, 2023

Related U.S. Application Data
(63) Continuation of application No. PCT/JP2022/001884, filed on Jan. 20, 2022.

(30) Foreign Application Priority Data
Feb. 17, 2021 (JP) 2021-023557

(51) Int. Cl. H01L 27/146

(52) U.S. Cl. CPC H01L 27/14616; H01L 27/14605; H01L 27/14636; H01L 27/14643

(57) ABSTRACT

An imaging device includes a semiconductor substrate including a reference region, a first impurity region, a second impurity region, an element isolation region, and a specific region. The reference region contains an impurity of a first conductivity type. Each of the first impurity region and the second impurity region is located in the reference region and contains an impurity of a second conductivity type. The element isolation region is located between the first impurity region and the second impurity region in plan view, and contains an impurity of the first conductivity type. The specific region is located between a surface of the semiconductor substrate and the element isolation region in a direction perpendicular to the surface, and contains an impurity of the second conductivity type.

### BACKGROUND

### 1. Technical Field

The present disclosure relates to an imaging device.

### 2. Description of the Related Art

A lamination type imaging device has been proposed as a metal oxide semiconductor (MOS) type imaging device. In the lamination type imaging device, a photoelectric conversion layer is laminated on a semiconductor substrate. Electric charges generated by photoelectric conversion in the photoelectric conversion layer are accumulated in a charge accumulation region. The imaging device reads out the accumulated charges by using either a charge coupled device (CCD) circuit or a complementary MOS (CMOS) circuit in the semiconductor substrate. For example, Japanese Unexamined Patent Application Publication No. 2019-212901 discloses such an imaging device.

### SUMMARY

In one general aspect, the techniques disclosed here feature an imaging device including a semiconductor substrate including a reference region, a first impurity region, a second impurity region, an element isolation region, and a specific region. The reference region contains an impurity of a first conductivity type. Each of the first impurity region and the second impurity region is located in the reference region and contains an impurity of a second conductivity type. The element isolation region is located between the first impurity region and the second impurity region in plan view, and contains an impurity of the first conductivity type. The specific region is located between a surface of the semiconductor substrate and the element isolation region in a direction perpendicular to the surface, and contains an impurity of the second conductivity type.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram illustrating an exemplary configuration of an imaging device according to an embodiment;

FIG. 2 is a schematic diagram illustrating an exemplary circuit configuration of the imaging device according to the embodiment;

FIG. 3 is a sectional view schematically illustrating an example of a device structure of a pixel of the imaging device according to the embodiment;

FIG. 4 is a schematic plan view illustrating a layout example of respective elements in the pixel of the imaging device according to the embodiment;

FIG. 5 is an explanatory diagram exemplifying a certain part of a manufacturing process of the imaging device according to the embodiment;

FIG. 6 is an explanatory diagram exemplifying another part of the manufacturing process of the imaging device according to the embodiment;

FIG. 7 is an explanatory diagram exemplifying another part of the manufacturing process of the imaging device according to the embodiment;

FIG. 8 is an explanatory diagram exemplifying another part of the manufacturing process of the imaging device according to the embodiment;

FIG. 9 is an explanatory diagram exemplifying another part of the manufacturing process of the imaging device according to the embodiment;

FIG. 10A is an enlarged layout diagram of a portion in the vicinity of a reset transistor in the embodiment;

FIG. 10B is an enlarged sectional view of the portion in the vicinity of the reset transistor in the embodiment;

FIG. 11A is an enlarged layout diagram of a portion in the vicinity of a charge accumulation region in the embodiment;

FIG. 11B is a layout diagram for exemplifying positional relations among a first contact hole, a p-n junction, an element isolation region, and a second contact hole in the embodiment;

FIG. 12A is a sectional view of the portion in the vicinity of the reset transistor in the embodiment;

FIG. 12B is a graph illustrating distribution of impurity concentrations in a direction perpendicular to a surface of a semiconductor substrate in the embodiment;

FIG. 13A is a sectional view of a portion in the vicinity of a reset transistor in a referential mode;

FIG. 13B is a graph illustrating distribution of impurity concentrations in a direction parallel to a surface of a semiconductor substrate in the referential mode;

FIG. 14A is a sectional view of the portion in the vicinity of the reset transistor in the embodiment;

FIG. 14B is a graph illustrating distribution of impurity concentrations in a direction parallel to the surface of the semiconductor substrate in the embodiment;

FIG. 15A is a sectional view illustrating distribution of a depletion layer in the vicinity of the reset transistor in the referential mode;

FIG. 15B is an energy level diagram of a charge accumulation region and an element isolation region in the referential mode;

FIG. 16A is a sectional view illustrating distribution of a depletion layer in the vicinity of the reset transistor in the embodiment;

FIG. 16B is an energy level diagram of the charge accumulation region and the element isolation region in the embodiment; and

FIG. 17 is a graph illustrating results of a test A.

### DETAILED DESCRIPTIONS

### Outline of Aspects According to Present Disclosure

An imaging device according to a first aspect of the present disclosure includes a semiconductor substrate including a reference region, a first impurity region, a second impurity region, an element isolation region, and a specific region.

The reference region contains an impurity of a first conductivity type.

Each of the first impurity region and the second impurity region is located in the reference region and contains an impurity of a second conductivity type.

The element isolation region is located between the first impurity region and the second impurity region in plan view, and contains an impurity of the first conductivity type.

The specific region is located between a surface of the semiconductor substrate and the element isolation region in a direction perpendicular to the surface, and contains an impurity of the second conductivity type.

The technique according to the first aspect is suitable for suppressing a leakage current between the first impurity region and the second impurity region.

According to a second aspect of the present disclosure, for example, in the imaging device according to the first aspect, the first impurity region may be a charge accumulation region that accumulates charges generated by photoelectric conversion.

The charge accumulation region is an example of the first impurity region.

According to a third aspect of the present disclosure, for example, in the imaging device according to the first or second aspect, the imaging device may further include a transistor including a source and a drain.

The second impurity region may be one of the source and the drain.

One of the source and the drain of the transistor is an example of the second impurity region.

According to a fourth aspect of the present disclosure, for example, in the imaging device according to any one of the first to third aspects,
a concentration of the impurity of the second conductivity type at a first point that belongs to the specific region may be higher than a concentration of the impurity of the first conductivity type at a second point that belongs to the element isolation region, and
an imaginary straight line that passes through the first point and the second point may be perpendicular to the surface.

The technique according to the fourth aspect is suitable for suppressing the leakage current between the first impurity region and the second impurity region.

According to a fifth aspect of the present disclosure, for example, in the imaging device according to any one of the first to fourth aspects,

the specific region may include a part in which a concentration of the impurity of the second conductivity type is greater than or equal to 1×10¹⁹ cm⁻³.

The technique according to the fifth aspect is suitable for suppressing the leakage current between the first impurity region and the second impurity region.

According to a sixth aspect of the present disclosure, for example, in the imaging device according to any one of the first to fifth aspects,
a concentration of the impurity of the second conductivity type at a third point that belongs to the specific region may be higher than a concentration of the impurity of the first conductivity type at a fourth point that belongs to the reference region, and
an imaginary straight line that passes through the third point, the fourth point, and a fifth point that belongs to the first impurity region in an enumerated order may be parallel to the surface.

The technique according to the sixth aspect is suitable for suppressing the leakage current between the first impurity region and the second impurity region.

According to a seventh aspect of the present disclosure, for example, in the imaging device according to any one of the first to sixth aspects,
a concentration of the impurity of the second conductivity type at a fifth point that belongs to the first impurity region may be higher than a concentration of the impurity of the first conductivity type at a fourth point that belongs to the reference region, and
an imaginary straight line that passes through a third point that belongs to the specific region, the fourth point, and the fifth point in an enumerated order may be parallel to the surface.

The technique according to the seventh aspect is suitable for suppressing the leakage current between the first impurity region and the second impurity region.

According to an eighth aspect of the present disclosure, for example, in the imaging device according to any one of the first to seventh aspects, the imaging device may further include an insulating layer disposed on the surface.

The specific region may be in contact with the insulating layer.

The configuration of the eighth aspect is one configuration example.

According to a ninth aspect of the present disclosure, for example, in the imaging device according to any one of the first to eighth aspects, the imaging device may further include: a first contact plug that contains a prescribed impurity of the second conductivity type.

The first impurity region may include a predetermined region, and

the predetermined region may be coupled to the first contact plug and may contain the prescribed impurity as the impurity of the second conductivity type.

The technique according to the ninth aspect is suitable for suppressing the leakage current between the first impurity region and the second impurity region.

According to a tenth aspect of the present disclosure, for example, in the imaging device according to the ninth aspect, the imaging device may further include: a first contact hole; a second contact plug; and second contact hole.

The first contact plug may be coupled to the predetermined region through the first contact hole,
the second contact plug may be coupled to the second impurity region through the second contact hole,
a p-n junction may be formed between the predetermined region and the reference region, and
the first contact hole, the p-n junction, the element isolation region, and the second contact hole may be arranged in an enumerated order on a straight line in plan view.

The technique according to the tenth aspect is suitable for suppressing the leakage current between the first impurity region and the second impurity region.

According to an eleventh aspect of the present disclosure, for example, in the imaging device according to any one of the first to tenth aspects, the specific region may contain phosphorus as the impurity of the second conductivity type.

The technique according to the eleventh aspect is suitable for suppressing the leakage current between the first impurity region and the second impurity region.

According to a twelfth aspect of the present disclosure, for example, in the imaging device according to any one of the first to eleventh aspects, the imaging device may further include: a first contact plug; and a first contact hole.

The first contact plug may be coupled to the first impurity region through the first contact hole, and

a distance between an end portion of the first contact hole and an end portion of the specific region may be longer than or equal to 50 nm and shorter than or equal to 500 nm in plan view.

The technique according to the twelfth aspect is suitable for suppressing the leakage current between the first impurity region and the second impurity region.

According to a thirteenth aspect of the present disclosure, for example, in the imaging device according to any one of the first to twelfth aspects, the imaging device may further include: a pixel region provided with at least one pixel; and a peripheral region provided with a peripheral circuit that controls the at least one pixel.

The pixel region may include the first impurity region, the second impurity region, the element isolation region, and the specific region,
the element isolation region may be an implanted isolation region, and
the peripheral region may include a shallow trench isolation structure.

The configuration of the thirteenth aspect is one configuration example.

According to a fourteenth aspect of the present disclosure, for example, in the imaging device according to any one of the first to thirteenth aspects,

the reference region may be disposed between the second impurity region and the specific region in plan view.

The fourteenth aspect is advantageous in light of avoiding conduction between the second impurity region and the specific region.

According to a fifteenth aspect of the present disclosure, for example, in the imaging device according to any one of the first to fourteenth aspects,

the imaging device may further include a plurality of pixels.

Each of the pixels may include the reference region, the first impurity region, the second impurity region, the element isolation region, and the specific region.

According to a sixteenth aspect of the present disclosure, for example, in the imaging device according to any one of the first to fifteenth aspects,

the reference region may be located between the first impurity region and the specific region.

According to a seventeenth aspect of the present disclosure, for example, in the imaging device according to any one of the first to sixteenth aspects,

each of the first impurity region and the second impurity region may be not in contact with the specific region.

According to an eighteenth aspect of the present disclosure, for example, in the imaging device according to any one of the first to seventeenth aspects,

the specific region may not contain an impurity of the first conductivity type.

According to a nineteenth aspect of the present disclosure, for example, in the imaging device according to any one of the first to eighteenth aspects,
the specific region may be in contact with the surface of the semiconductor substrate, and
the element isolation region may be not in contact with the surface of the semiconductor substrate.

According to a twentieth aspect of the present disclosure, for example, in the imaging device according to any one of the first to nineteenth aspects,
a p-n junction may be formed between the specific region and the element isolation region, and
a distance between the surface of the semiconductor substrate and the p-n junction in the direction perpendicular to the surface may be longer than or equal to 5 nm and shorter than or equal to 30 nm.

An embodiment according to the present disclosure will be described below with reference to the drawings.

In the embodiment, “plan view” means a view in a direction perpendicular to a semiconductor substrate.

In the embodiment, a region among n-type impurity regions which has a higher concentration of an n-type impurity may be referred to as an n⁺-type impurity region.

Ordinal numbers such as first, second, and third may be used in the embodiment. When ordinal numbers are provided to certain elements, the existence of the same element with a smaller ordinal number is not essential. The ordinal numbers may be interchanged as appropriate.

In the embodiment, the constituents are appropriately adjusted in association with different polarities of signal charges attributed to a change in conductivity type of an impurity region and the like. In addition, terms will be translated as appropriate in association with the different polarities of signal charges.

The present disclosure is not limited only to the following embodiment. Various changes are possible as appropriate within the range not departing from the scope that does not deviate from the effects of the present disclosure. In addition, it is also possible to combine one embodiment with another embodiment. In the following description, identical or similar constituents will be denoted by identical reference signs. In the meantime, overlapping explanations may be omitted as appropriate.

### EMBODIMENT 1

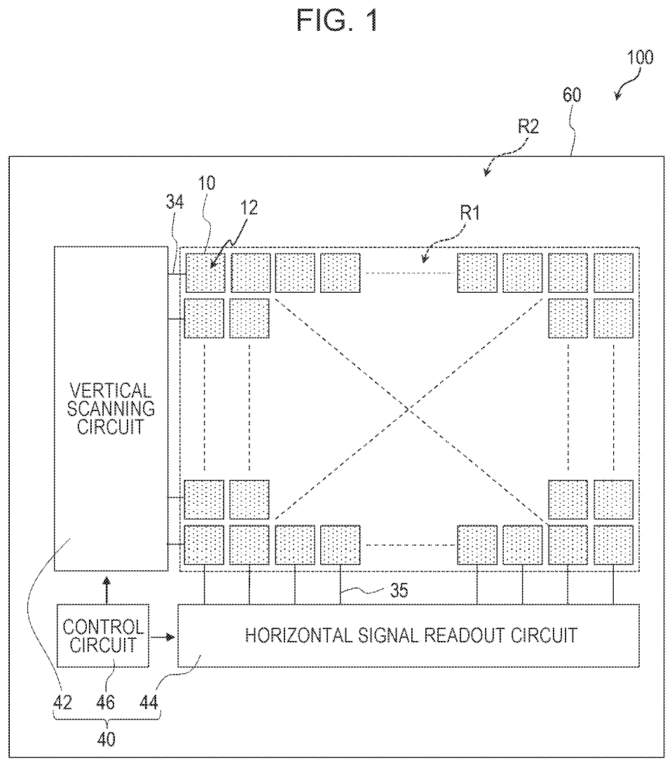

Structures and functions of an imaging device according to Embodiment 1 will be described with reference to FIGS. 1 to 4.

FIG. 1 is a block diagram illustrating an exemplary configuration of an imaging device 100 according to the Embodiment 1. The imaging device 100 illustrated in FIG. 1 includes pixels 10 and peripheral circuits 40. The pixels 10 and the peripheral circuits 40 are provided by using a semiconductor substrate 60. In the present embodiment, the semiconductor substrate 60 is a silicon substrate. Each pixel 10 includes a photoelectric converter 12. The photoelectric converter 12 converts light into electric charges.

In the example illustrated in FIG. 1, the pixels 10 are arranged in m rows and in n columns. Here, each of the codes m and n independently represents an integer greater than or equal to 1. The pixels 10 are two-dimensionally arranged on the semiconductor substrate 60, for example, thereby forming an imaging region R1. The imaging region R1 is also referred to as a pixel region.

The number and the layout of the pixels 10 are not limited only to the illustrated example. In this example, the center of each pixel 10 is located on a grid point of a square grid. Instead, the center of each pixel 10 may be located on a grid point of a triangular grid or a hexagonal grid. The pixels 10 may be arranged one-dimensionally. In this case, the imaging device 100 can be used as a line sensor. The number of the pixels 10 included in the imaging device 100 may be one.

In the configuration exemplified in FIG. 1, the peripheral circuits 40 include a vertical scanning circuit 42 and a horizontal signal readout circuit 44. As exemplified in FIG. 1, the peripheral circuits 40 can additionally include a control circuit 46. Moreover, the peripheral circuits 40 can further include a voltage supply circuit that supplies a predetermined voltage to the pixels 10 and the like, for example. The peripheral circuits 40 may further include a signal processing circuit or an output circuit.

The peripheral circuits 40 are provided in a peripheral region R2 located on the periphery of the imaging region R1, for example. In the example illustrated in FIG. 1, the peripheral region R2 is an L-shaped region extending along two sides of the imaging region R1. Instead, the peripheral region R2 may be an annular region that surrounds the imaging region R1. The peripheral region R2 may be an elongate region that extends along one side of the imaging region R1.

An address signal line 34 is provided for each row of the pixels 10. The address signal lines 34 are coupled to the vertical scanning circuit 42. The vertical scanning circuit 42 is also referred to as a row scanning circuit. The respective rows of the pixels 10 may be provided with different signal lines, and these signal lines may be coupled to the vertical scanning circuit 42. In other words, two or more types of signal lines may be provided to each row of the pixels 10, and these signal lines may be coupled to the vertical scanning circuit 42.

A vertical signal line 35 is provided for each column of the pixels 10. The vertical signal lines 35 are coupled to the horizontal signal readout circuit 44. The horizontal signal readout circuit 44 is also referred to as a column scanning circuit.

The control circuit 46 receives instruction data and a clock, for example, and controls the entire imaging device 100. The instruction data and the clock are provided from outside of the imaging device 100, for example. The control circuit 46 typically includes a timing generator. The control circuit 46 can supply driving signals to the vertical scanning circuit 42 and the horizontal signal readout circuit 44. In FIG. 1, arrows extending from the control circuit 46 schematically represent flows of output signals from the control circuit 46. The control circuit 46 can be realized by a microcontroller that includes one or more processors, for example. Functions of the control circuit 46 may be realized by a combination of a general-purpose processing circuit and software, or may be realized by hardware specialized in such processing.

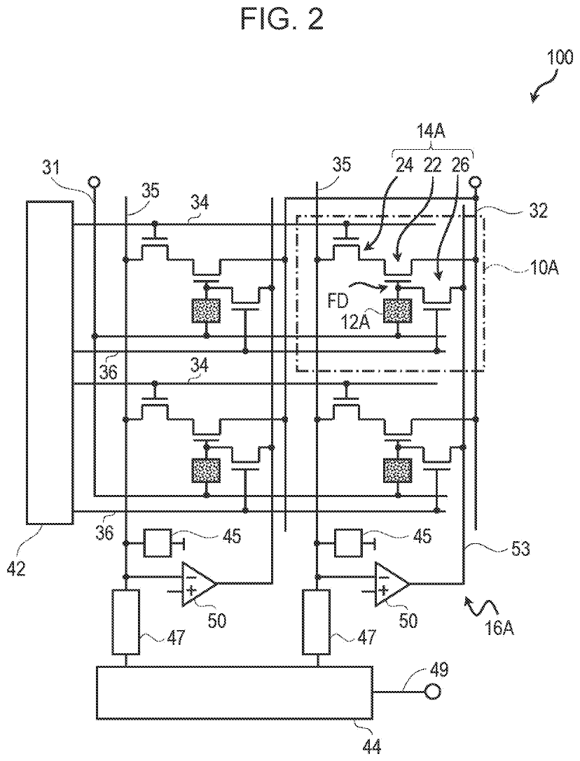

FIG. 2 is a schematic diagram illustrating an exemplary circuit configuration of the imaging device 100 according to the Embodiment 1 of the present disclosure. In order to avoid complexity of the drawing, FIG. 2 representatively illustrates four pixels 10A arranged in two rows and two columns. Each of these pixels 10A represents an example of the pixel 10 illustrated in FIG. 1.

Each pixel 10A includes a photoelectric conversion structure 12A and a signal detection circuit 14A. The photoelectric conversion structure 12A is provided as the photoelectric converter 12. The signal detection circuit 14A is electrically coupled to the photoelectric conversion structure 12A. As will be described later in detail with reference to the drawings, the photoelectric conversion structure 12A includes a photoelectric conversion layer disposed above the semiconductor substrate 60. Specifically, a lamination type imaging device is exemplified here as the imaging device 100. However, the photoelectric converter 12 may be a photodiode provided in the semiconductor substrate.

Note that the terms such as “above”, “below”, “upper surface”, and “lower surface” in the present embodiment are merely used for indicating relative layouts among constituents and are not intended to limit the posture of the imaging device 100 while the device is in use.

In the configuration exemplified in FIG. 2, the photoelectric conversion structure 12A of each pixel 10A is coupled to an accumulation control line 31. When the imaging device 100 is in operation, a predetermined voltage is applied to the accumulation control line 31. In a case of using, as signal charges, positive charges out of positive and negative charges generated by photoelectric conversion, for example, a positive voltage around 10 V can be applied to the accumulation control line 31 when the imaging device 100 is in operation, for instance. A case of using holes as the signal charges will be exemplified in the following description.

In the configuration exemplified in FIG. 2, each signal detection circuit 14A includes a signal detection transistor 22, an address transistor 24, and a reset transistor 26. As will be described later in detail with reference to the drawings, each of the signal detection transistor 22, the address transistor 24, and the reset transistor 26 is typically a field effect transistor provided to the semiconductor substrate 60 that supports the photoelectric conversion structure 12A. A case of using a metal oxide semiconductor field effect transistor (MOSFET) as the transistor will be described below unless otherwise specifically stated. To be more precise, each transistor is an n-channel MOSFET in the following example.

As schematically illustrated in FIG. 2, a gate electrode of the signal detection transistor 22 is electrically coupled to the photoelectric conversion structure 12A. Application of a predetermined voltage to the accumulation control line 31 at the time of operation makes it possible to accumulate the holes as the signal charges in a charge accumulation region FD, for example.

In the present embodiment, the charge accumulation region FD is an impurity region provided to the semiconductor substrate 60. In the illustrated example, the charge accumulation region FD accumulates the charges generated by the photoelectric conversion structure 12A. Here, the imaging device 100 may include a portion other than the charge accumulation region FD in order to temporarily retain the charges generated by the photoelectric conversion structure 12A. Examples of such a portion include a pixel electrode 12a, a conducting structure 89, the gate electrode of the signal detection transistor 22, and the like.

One of a source and a drain of the signal detection transistor 22 is coupled to a power supply line 32. The power supply line 32 supplies a power supply voltage VDD to each pixel 10A when the imaging device 100 is in operation. The power supply voltage VDD is set to 3.3 V, for example. The other one of the source and the drain of the signal detection transistor 22 is coupled to the vertical signal line 35 through the address transistor 24. As a consequence of receiving the supply of the power supply voltage VDD with one of the source and the drain, the signal detection transistor 22 outputs a signal voltage corresponding to an amount of the signal charges accumulated in the charge accumulation region FD.

The address signal line 34 is coupled to a gate electrode of the address transistor 24 that is coupled between signal detection transistor 22 and the vertical signal line 35. By applying a row selection signal to control on and off states of the address transistor 24 to the address signal line 34, the vertical scanning circuit 42 can read output from the signal detection transistor 22 of the selected pixel 10A out to the corresponding vertical signal line 35. Here, the layout of the address transistor 24 is not limited only to the example illustrated in FIG. 2. The address transistor 24 may be located between the drain of the signal detection transistor 22 and the power supply line 32.

A load circuit 45 and a column signal processing circuit 47 are coupled to each vertical signal line 35. The load circuit 45 forms a source follower circuit in conjunction with the signal detection transistor 22. The column signal processing circuit 47 is also referred to as a row signal accumulation circuit. The column signal processing circuit 47 performs noise suppression signal processing and analog-to-digital conversion, for example. The noise suppression signal processing is correlated double sampling, for instance. The horizontal signal readout circuit 44 sequentially reads signals out of the column signal processing circuits 47 to a horizontal common signal line 49. The load circuit 45 and the column signal processing circuit 47 can be part of the peripheral circuits 40.

A reset signal line 36 is coupled to a gate electrode of the reset transistor 26. The reset signal line 36 is coupled to the vertical scanning circuit 42. The reset signal line 36 is provided to each row of the pixels 10A as with the address signal line 34. The vertical scanning circuit 42 can select the pixels 10A of resetting targets on the row basis by applying the row selection signal to the address signal line 34. Moreover, the vertical scanning circuit 42 can switch on and off states of the reset transistors 26 of the selected row by applying a reset signal to gates of the reset transistors 26 through the reset signal line 36. An electric potential of each charge accumulation region FD is reset by turning on the corresponding reset transistor 26.

In this example, one of a source and a drain of each reset transistor 26 constitutes the charge accumulation region FD. A feedback line 53 is provided to each column of the pixels 10A. The feedback line 53 is associated with the reset transistors 26. The other one of the source and the drain of the reset transistor 26 is coupled to the corresponding feedback line 53. In this example, a voltage on the feedback line 53 is supplied to the charge accumulation region FD as a reset voltage for initializing the charges in the photoelectric converter 12.

In the configuration exemplified in FIG. 2, the imaging device 100 includes a feedback circuit 16A. A feedback channel including an inverting amplifier 50 is formed from the feedback circuit 16A. As illustrated in FIG. 2, the inverting amplifier 50 is provided to each column of the pixels 10A. The feedback line 53 is also associated with the inverting amplifier 50. The feedback line 53 is coupled to an output terminal of the corresponding inverting amplifier 50. The inverting amplifier 50 can be part of the peripheral circuits 40.

As illustrated in FIG. 2, an inverting input terminal of the inverting amplifier 50 is coupled to the vertical signal line 35 of the corresponding column. A reference voltage Vref is supplied to a non-inverting input terminal of the inverting amplifier 50 when the imaging device 100 is in operation. The feedback channel for negatively feeding back the output of a certain pixel 10A can be formed by turning on the address transistor 24 and the reset transistor 26 of the certain pixel 10A. As a consequence of formation of the feedback channel, the voltage on the vertical signal line 35 converges to the reference voltage Vref being an input voltage to the non-inverting input terminal of the inverting amplifier 50. In other words, as a consequence of formation of the feedback channel, the voltage in the charge accumulation region FD is reset to such a voltage that makes the voltage on the vertical signal line 35 equal to the reference voltage Vref. A voltage having any magnitude within a range between the power supply voltage and ground potential can be used as the reference voltage Vref. The reference voltage Vref is a positive voltage equal to 1 V or in the vicinity of 1 V, for example. Formation of the feedback channel makes it possible to reduce reset noise that may be generated along with turning the reset transistor 26 off.

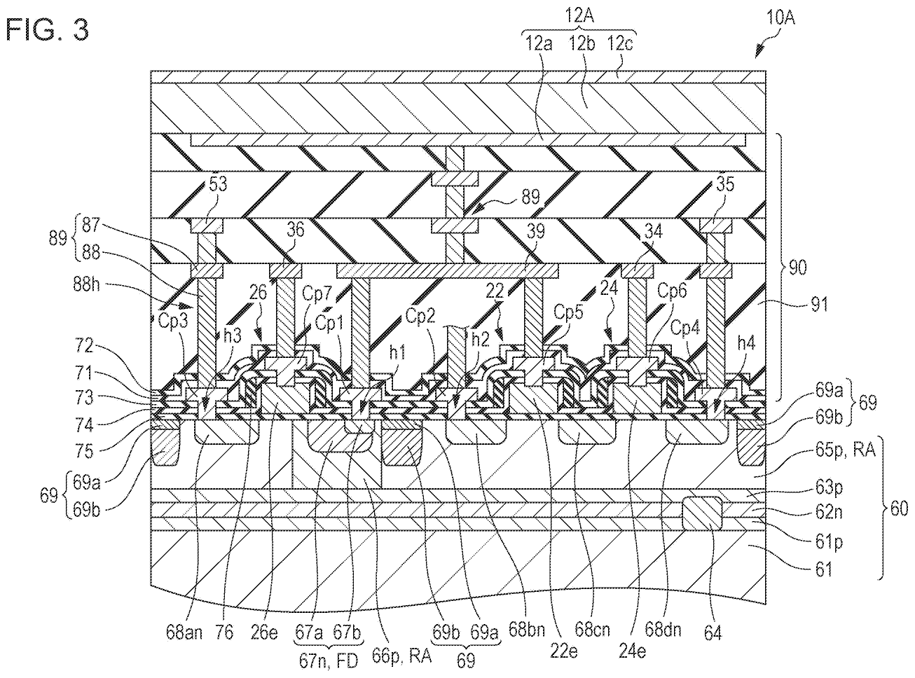

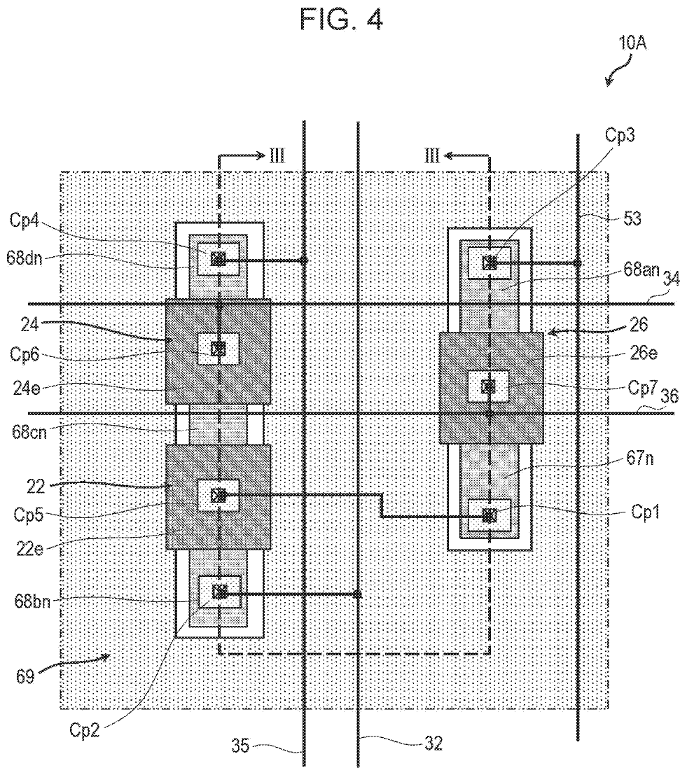

Next, details of a device structure of the pixel 10A will be described with reference to FIGS. 3 and 4.

FIG. 3 is a sectional view schematically illustrating an example of a device structure of the pixel 10A of the imaging device 100 according to the Embodiment 1 of the present disclosure. FIG. 4 is a schematic plan view illustrating a layout example of respective elements in the pixel 10A of the imaging device 100 according to the present embodiment. FIG. 4 schematically illustrates a layout of the elements formed on the semiconductor substrate 60 when the pixel 10A illustrated in FIG. 3 is viewed in a direction normal to the semiconductor substrate 60. A cross-section illustrated in FIG. 3 is obtained by cutting and spreading the pixel 10A along the III-III line in FIG. 4.

In order to simplify the schematic diagram, illustration of a p-type semiconductor layer 65p, a p-type semiconductor layer 66p, a first insulating layer 71, a second insulating layer 72, a third insulating layer 73, a fourth insulating layer 74, a fifth insulating layer 75, and the like is omitted in FIG. 4.

Reference is made to FIG. 3. The pixel 10A includes the semiconductor substrate 60, the photoelectric conversion structure 12A, and a conducting structure 89. As illustrated in FIG. 3, the photoelectric conversion structure 12A is disposed above the semiconductor substrate 60. To be more precise, the photoelectric conversion structure 12A is supported by an interlayer insulating layer 90 that covers the semiconductor substrate 60. The conducting structure 89 is disposed inside the interlayer insulating layer 90.

In the illustrated example, the interlayer insulating layer 90 includes multiple insulating layers. The insulating layers include a seventh insulating layer 91. The seventh insulating layer 91 may also be referred to as a pre-metal-dielectric film. The conducting structure 89 includes via plugs 88. Moreover, the conducting structure 89 includes parts of respective wiring layers. Such parts are disposed inside the interlayer insulating layer 90. In the present embodiment, each via plug 88 is a metal plug. The via plug 88 is housed in a coupling hole 88h.

The wiring layers disposed inside the interlayer insulating layer 90 may be provided with a wiring layer that partially includes at least one of the address signal line 34, the reset signal line 36, the vertical signal line 35, the power supply line 32, or the feedback line 53, for example. The number of the insulating layers and the number of the wiring layers in the interlayer insulating layer 90 are not limited to the aforementioned examples. The number of the insulating layers and the number of the wiring layers can be set to any numbers.

A term “metal wiring 87” may be used in the following description. The metal wiring 87 is wiring included in the conducting structure 89. For example, the metal wiring 87 may correspond to part of the address signal line 34, the reset signal line 36, the vertical signal line 35, the power supply line 32, the feedback line 53, and the like.

The photoelectric conversion structure 12A includes the pixel electrode 12a, a counter electrode 12c, and a photoelectric conversion layer 12b. The photoelectric conversion layer 12b is disposed between the pixel electrode 12a and the counter electrode 12c. The pixel electrode 12a is provided on the interlayer insulating layer 90. The counter electrode 12c is disposed on a light incident side.

The material of the photoelectric conversion layer 12b may be either an organic material or an inorganic material. The inorganic material is amorphous silicon, for instance. The photoelectric conversion layer 12b receives light incident through the counter electrode 12c, and generates positive and negative charges by photoelectric conversion. The photoelectric conversion layer 12b is typically provided continuously across the pixels 10A. The photoelectric conversion layer 12b may include a layer formed from the organic material and a layer formed from the inorganic material. The photoelectric conversion layer 12b may be separately provided to each pixel 10A.

The counter electrode 12c is a transparent electrode formed from a transparent conductive material. The transparent conductive material is indium tin oxide (ITO), for example. The term “transparent” in the present embodiment means transmitting at least part of light at a wavelength that can be absorbed by the photoelectric conversion layer 12b, and it is not essential to transmit the light across the entire wavelength range of the visible light. Typically, the counter electrode 12c is provided continuously across the pixels 10A as with the photoelectric conversion layer 12b. In other words, the counter electrode 12c is used by two or more pixels 10A in common. The counter electrode 12c may be separately provided to each pixel 10A.

Although illustration is omitted in FIG. 3, the counter electrode 12c is coupled to the accumulation control line 31. An electric potential of the counter electrode 12c is set higher than an electric potential of the pixel electrode 12a by controlling an electric potential of the accumulation control line 31 when the imaging device 100 is in operation, for example. This makes the pixel electrode 12a possible to selectively collect the positive charges out of the positive and negative charges generated by photoelectric conversion. When the counter electrode 12c is continuously provided across the two or more pixels 10A, it is possible to collectively apply a predetermined voltage to the counter electrode 12c of the pixels 10A.

Examples of the material of the pixel electrode 12a include a metal, a metal nitride, and the like. The material of the pixel electrode 12a may be polysilicon provided with conductivity by being doped with an impurity. Examples of the metal include aluminum, copper, and the like. Each pixel electrode 12a is spatially isolated from a pixel electrode 12a of a different pixel 10A adjacent thereto, thus being electrically isolated from the pixel electrode 12a of the different pixel 10A.

The conducting structure 89 includes multiple wires and plugs. One end of the conducting structure 89 is coupled to the pixel electrode 12a. The other end of the conducting structure 89 is coupled to the charge accumulation region FD. In the illustrated example, the charge accumulation region FD is an n-type impurity region 67n. Examples of the material of the wires and the plugs include a metal, a metal compound, and the like. Examples of the metal include copper, tungsten, and the like. Examples of the metal compound include a metal nitride, a metal oxide, and the like. The material of the wires and the plugs may be polysilicon provided with conductivity. The pixel electrode 12a of the photoelectric converter 12 and a circuit on the semiconductor substrate 60 can be electrically coupled to each other by coupling a circuit element provided to the semiconductor substrate 60 to the other end of the conducting structure 89.

Now, attention is given to the semiconductor substrate 60. As schematically illustrated in FIG. 3, the semiconductor substrate 60 includes a support substrate 61, and one or more semiconductor layers provided on the support substrate 61. Here, a p-type silicon substrate is exemplified as the support substrate 61.

In the configuration exemplified in FIG. 3, the semiconductor substrate 60 includes a p-type semiconductor layer 61p, an n-type semiconductor layer 62n, a p-type semiconductor layer 63p, and the p-type semiconductor layer 65p. The p-type semiconductor layer 61p is located on the support substrate 61. The n-type semiconductor layer 62n is located on the p-type semiconductor layer 61p. The p-type semiconductor layer 63p is located on the n-type semiconductor layer 62n. The p-type semiconductor layer 65p is located on the p-type semiconductor layer 63p.

The p-type semiconductor layer 63p is typically provided across the entire surface of the support substrate 61. Each of the n-type semiconductor layer 62n, the p-type semiconductor layer 63p, and the p-type semiconductor layer 65p is typically formed by ion implantation of an impurity into a semiconductor layer that is formed by epitaxial growth.

Impurity concentrations of the p-type semiconductor layer 63p and the p-type semiconductor layer 65p are higher than an impurity concentration of the p-type semiconductor layer 61p. Here, the impurity concentration of the p-type semiconductor layer 63p is higher than that of the p-type semiconductor layer 65p. The impurity concentration of the p-type semiconductor layer 61p is about 10¹⁵ cm⁻³ and the impurity concentration of the p-type semiconductor layer 65p is about 10¹⁷ cm⁻³. The impurity concentration of the p-type semiconductor layer 63p can be in a range from 10¹⁷ cm⁻³ to 10¹⁸ cm⁻³, for example. The above-mentioned correlations of the impurity concentrations are mere examples, and it is also possible to adopt a configuration in which the impurity concentrations of the p-type semiconductor layer 63p and the p-type semiconductor layer 65p are almost equal to each other. Alternatively, the impurity concentration of the p-type semiconductor layer 65p can be set higher than the impurity concentration of the p-type semiconductor layer 63p.

The n-type semiconductor layer 62n is located between the p-type semiconductor layer 61p and the p-type semiconductor layer 63p. Although illustration is omitted in FIG. 3, a well contact is coupled to the n-type semiconductor layer 62n. The well contact is provided outside the imaging region R1, and an electric potential of the n-type semiconductor layer 62n is controlled through the well contact when the imaging device 100 is in operation. As a consequence of providing the n-type semiconductor layer 62n, minority carriers are kept from flowing from the support substrate 61 or the peripheral circuits 40 into the charge accumulation region FD that accumulates the signal charges.

Moreover, the semiconductor substrate 60 includes a p-type region 64 in this example. The p-type region 64 is provided between the p-type semiconductor layer 63p and the support substrate 61 in such a way as to penetrate the p-type semiconductor layer 61p and the n-type semiconductor layer 62n. The p-type region 64 has a higher impurity concentration than those of the p-type semiconductor layer 63p and the p-type semiconductor layer 65p. The p-type region 64 electrically couples the p-type semiconductor layer 63p to the support substrate 61.

Although illustration is omitted in FIG. 3, the support substrate 61 is coupled to a substrate contact provided on the outside of the imaging region R1. When the imaging device 100 is in operation, electric potentials of the support substrate 61 and the p-type semiconductor layer 63p are controlled through the substrate contact. Meanwhile, by disposing the p-type semiconductor layer 65p in such a way as to be in contact with the p-type semiconductor layer 63p, it is possible to control an electric potential of the p-type semiconductor layer 65p through the p-type semiconductor layer 63p when the imaging device 100 is in operation. Note that the p-type semiconductor layer 65p is provided as a p-well.

In the configuration exemplified in FIG. 3, the p-type semiconductor layer 66p is located in the p-type semiconductor layer 65p. An impurity concentration of the p-type semiconductor layer 66p is lower than the impurity concentration of the p-type semiconductor layer 65p.

The n-type impurity region 67n is an example of the charge accumulation region FD. In the configuration exemplified in FIG. 3, the n-type impurity region 67n is located in the p-type semiconductor layer 66p. Moreover, the n-type impurity region 67n is located in the vicinity of a surface of the semiconductor substrate 60. At least part of the n-type impurity region 67n is in contact with the surface of the semiconductor substrate 60.

The n-type impurity region 67n includes a first region 67a and a second region 67b. An impurity concentration of the second region 67b is higher than an impurity concentration of the first region 67a. The second region 67b is an n⁺-type impurity region.

The p-type semiconductor layer 66p is provided as a p-well. Junction capacitance formed by a p-n junction between the p-type semiconductor layer 66p and the n-type impurity region 67n functions as a capacitor for accumulating at least part of the signal charges. In this way, the n-type impurity region 67n functions as the charge accumulation region FD that temporarily retains the signal charges.

As described above, the electric potential of the p-type semiconductor layer 65p can be controlled through the p-type semiconductor layer 63p when the imaging device 100 is in operation by disposing the p-type semiconductor layer 65p adjacent to the p-type semiconductor layer 63p. By adopting the above-described structure, it is possible to dispose a region having a relatively low impurity concentration around a portion where the semiconductor substrate 60 is in contact with a contact plug Cp1 that is electrically coupled to the photoelectric conversion structure 12A. In other words, the first region 67a and the p-type semiconductor layer 66p can be disposed around the second region 67b as in this example.

In the example illustrated in FIG. 3, the first region 67a and the p-type semiconductor layer 66p spread on the p-type semiconductor layer 63p side and on a gate electrode 26e side of the reset transistor when viewed from the second region 67b. The p-n junction between the n-type impurity region 67n and the p-type semiconductor layer 66p on these sides is a p-n junction between the first region 67a and the p-type semiconductor layer 66p. The impurity concentration of the first region 67a is lower than the impurity concentration of the second region 67b, and an impurity concentration of the p-type semiconductor layer 66p is lower than the impurity concentration of the p-type semiconductor layer 65p. Since the p-n junction is formed by using the first region 67a and the p-type semiconductor layer 66p as described above, an electric field intensity formed by the p-n junction can be relaxed. As a consequence, a leakage current attributed to the electric field can be suppressed.

Meanwhile, the p-type semiconductor layer 66p spreads on a shield structure 69 side when viewed from the second region 67b. The p-n junction between the n-type impurity region 67n and the p-type semiconductor layer 66p on this side is a p-n junction between the second region 67b and the p-type semiconductor layer 66p. Although the impurity concentration of the second region 67b is higher than the impurity concentration of the first region 67a, the impurity concentration of the p-type semiconductor layer 66p is lower than the impurity concentration of the p-type semiconductor layer 65p. Since the p-n junction is formed by using the p-type semiconductor layer 66p as described above, an electric field intensity formed by the p-n junction can be relaxed. As a consequence, a leakage current attributed to the electric field can be suppressed.

In the configuration exemplified in FIG. 3, an n-type impurity region 68an, an n-type impurity region 68bn, an n-type impurity region 68cn, and an n-type impurity region 68dn are located in the p-type semiconductor layer 65p. The n-type impurity region 68an also includes a first region having a relatively low impurity concentration and a second region having a relatively high impurity concentration as with the n-type impurity region 67n. The second region is an n⁺-type impurity region. These features also apply to the n-type impurity regions 68bn, 68cn, and 68dn.

The shield structure 69 is located between the p-type semiconductor layer 65p and the p-type semiconductor layer 66p. The shield structure 69 includes a specific region 69a and an element isolation region 69b. The specific region 69a and the element isolation region 69b are stacked on each other. A p-n junction is formed between the specific region 69a and the element isolation region 69b. The specific region 69a is located closer to the surface of the semiconductor substrate 60 than the element isolation region 69b is. The element isolation region 69b is located closer to the support substrate 61 than the specific region 69a is.

The specific region 69a is an n-type impurity region. To be more precise, the specific region 69a is an n⁺-type impurity region. On the other hand, the element isolation region 69b is a p-type semiconductor layer. In the example of FIG. 3, the element isolation region 69b is an implanted isolation region formed by ion implantation.

FIG. 3 illustrates three shield structures 69. One shield structure 69 is located between the n-type impurity region 68an and an end portion of the pixel 10A. Another shield structure 69 is located between the charge accumulation region FD and the n-type impurity region 68bn within the pixel 10A. Still another shield structure 69 is located between the n-type impurity region 68dn and another end portion of the pixel 10A.

As understood from FIGS. 3 and 4, the p-type semiconductor layer 65p is disposed between the n-type impurity region 68an and the shield structure 69 in plan view. This arrangement makes it easier to avoid conduction between the n-type impurity region 68an and the specific region 69a of the shield structure 69 both of which are of the n-type. This aspect is advantageous from the viewpoint of normally operating the reset transistor 26. Here, a portion of the p-type semiconductor layer 65p between the n-type impurity region 68an and the shield structure 69 will be defined as a first p-type semiconductor section. In this instance, a distance from the p-n junction between the n-type impurity region 68an and the first p-type semiconductor section to the p-n junction between the first p-type semiconductor section and the specific region 69a at a position with a depth of 1 nm from the surface of the semiconductor substrate 60 is set longer than or equal to 50 nm, for example.

The p-type semiconductor layer 65p is disposed between the n-type impurity region 68bn and the shield structure 69 in plan view. This arrangement makes it easier to avoid conduction between the n-type impurity region 68bn and the specific region 69a of the shield structure 69 both of which are of the n-type. This aspect is advantageous from the viewpoint of normally operating the signal detection transistor 22. Here, a portion of the p-type semiconductor layer 65p between the n-type impurity region 68bn and the shield structure 69 will be defined as a second p-type semiconductor section. In this instance, a distance from the p-n junction between the n-type impurity region 68bn and the second p-type semiconductor section to the p-n junction between the second p-type semiconductor section and the specific region 69a at a position with the depth of 1 nm from the surface of the semiconductor substrate 60 is set to longer than or equal to 50 nm, for example.

The p-type semiconductor layer 65p is disposed between the n-type impurity region 68cn and the shield structure 69 in plan view. This arrangement makes it easier to avoid conduction between the n-type impurity region 68cn and the specific region 69a of the shield structure 69 both of which are of the n-type. This aspect is advantageous from the viewpoint of normally operating the signal detection transistor 22 and the address transistor 24. Here, a portion of the p-type semiconductor layer 65p between the n-type impurity region 68cn and the shield structure 69 will be defined as a third p-type semiconductor section. In this instance, a distance from the p-n junction between the n-type impurity region 68cn and the third p-type semiconductor section to the p-n junction between the third p-type semiconductor section and the specific region 69a at a position with the depth of 1 nm from the surface of the semiconductor substrate 60 is set to longer than or equal to 50 nm, for example.

The p-type semiconductor layer 65p is disposed between the n-type impurity region 68dn and the shield structure 69 in plan view. This arrangement makes it easier to avoid conduction between the n-type impurity region 68dn and the specific region 69a of the shield structure 69 both of which are of the n-type. This aspect is advantageous from the viewpoint of normally operating the address transistor 24. Here, a portion of the p-type semiconductor layer 65p between the n-type impurity region 68dn and the shield structure 69 will be defined as a fourth p-type semiconductor section. In this instance, a distance from the p-n junction between the n-type impurity region 68dn and the fourth p-type semiconductor section to the p-n junction between the fourth p-type semiconductor section and the specific region 69a at a position with the depth of 1 nm from the surface of the semiconductor substrate 60 is set to longer than or equal to 50 nm, for example.

In the configuration exemplified in FIG. 3, the contact plug Cp1 is coupled to the second region 67b being the n-type impurity region through the third insulating layer 73, the fourth insulating layer 74, and the fifth insulating layer 75. A contact plug Cp2 is coupled to the n-type impurity region 68bn through the third insulating layer 73, the fourth insulating layer 74, and the fifth insulating layer 75. A contact plug Cp3 is coupled to the n-type impurity region 68an through the third insulating layer 73, the fourth insulating layer 74, and the fifth insulating layer 75. A contact plug Cp4 is coupled to the n-type impurity region 68dn through the third insulating layer 73, the fourth insulating layer 74, and the fifth insulating layer 75. A contact plug Cp5 is coupled to a gate electrode 22e through the third insulating layer 73 and the fourth insulating layer 74. A contact plug Cp6 is coupled to a gate electrode 24e through the third insulating layer 73 and the fourth insulating layer 74. A contact plug Cp7 is coupled to the gate electrode 26e through the third insulating layer 73 and the fourth insulating layer 74.

Each of the contact plugs Cp1 to Cp7 is doped with an impurity at a high concentration. To be more precise, the impurity is phosphorus. The high impurity concentration of the second region 67b of the n-type impurity region 67n is achieved by diffusion of the impurity from the contact plug Cp1 Likewise, the high impurity concentrations of the second regions of the n-type impurity regions 68an, 68bn, and 68dn are achieved by diffusion of the impurity from the contact plugs Cp3, Cp2, and Cp4, respectively.

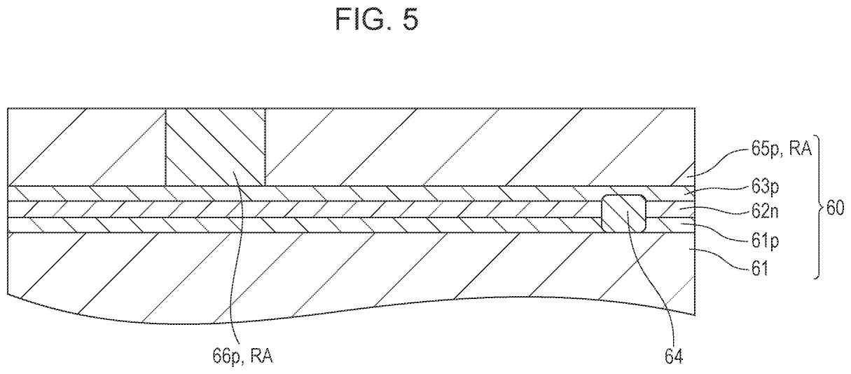

FIGS. 5 to 9 are diagrams exemplifying parts of a manufacturing process of the imaging device 100 according to the Embodiment 1. Now, a sequence of the manufacturing process concerning the shield structure 69 will be exemplarily described below with reference to FIGS. 5 to 9. In the following description, a range Rp and a peak concentration will be used as indices of ion implantation. The range Rp is equivalent to an ion implantation depth. The range Rp means a depth where a peak value of the impurity concentration is obtained.

In FIG. 5, each of the p-type semiconductor layer 61p, the n-type semiconductor layer 62n, and the p-type semiconductor layer 63p is formed by ion implantation of an impurity into the semiconductor layer that is formed by epitaxial growth. The p-type impurity to be implanted into the p-type semiconductor layer 61p is boron. The impurity concentration of the p-type semiconductor layer 61p is in a range from about 1×10¹⁵ cm⁻³ to 5×10¹⁵ cm⁻³. The n-type impurity to be implanted into the n-type semiconductor layer 62n is phosphorus. The range Rp of the impurity in the n-type semiconductor layer 62n from the surface of the semiconductor substrate 60 is in a range from 1300 nm to 1600 nm. The peak concentration of the impurity in the n-type semiconductor layer 62n is in a range from about 2×10¹⁶ cm⁻³ to 8×10¹⁶ cm⁻³. The p-type impurity to be implanted into the p-type semiconductor layer 63p is boron. The range Rp of the impurity in the p-type semiconductor layer 63p from the surface of the semiconductor substrate 60 is in a range from 800 nm to 1000 nm. The peak concentration of the impurity in the p-type semiconductor layer 63p is in a range from about 1×10¹⁷ cm⁻³ to 5×10¹⁷ cm⁻³. Here, the symbol “×” means a multiplication.

In FIG. 5, the p-type region 64 is formed by photolithography and ion implantation. A thickness of a photoresist film used for the photolithography is from about 4 μm to 5 μm. A pattern size to be formed is in a range from about 500 nm to 1000 nm. The ion implantation takes place in multiple steps. Specifically, the ion implantation takes place in two steps. The p-type impurity to be implanted is boron. In the ion implantation in a first step, the range Rp of the impurity from the surface of the semiconductor substrate 60 is in a range from 1100 nm to 1400 nm. The peak concentration of the impurity in the p-type region 64 originating from the ion implantation in the first step is in a range from about 1×10¹⁷ cm⁻³ to 5×10¹⁷ cm⁻³. In the ion implantation in a second step, the range Rp of the impurity from the surface of the semiconductor substrate 60 is in a range from 1300 nm to 1600 nm. The peak concentration of the impurity in the p-type region 64 originating from the ion implantation in the second step is in a range from about 3×10¹⁷ cm⁻³ to 9×10¹⁷ cm⁻³.

In FIG. 5, the p-type semiconductor layer 65p is formed by photolithography and ion implantation. A region corresponding to the p-type semiconductor layer 66p is covered with a photoresist by photolithography. Meanwhile, in a region corresponding to the p-type semiconductor layer 65p, an opening is formed by removing the photoresist. Since the ion implantation takes place in this state, the ions are not implanted into the region corresponding to the p-type semiconductor layer 66p, whereas the ions are implanted into the region corresponding to the p-type semiconductor layer 65p. The ion implantation takes place in multiple steps. Specifically, the ion implantation takes place in two steps. The p-type impurity to be implanted is boron. In the ion implantation in a first step, the range Rp of the impurity from the surface of the semiconductor substrate 60 is in a range from 300 nm to 500 nm. The peak concentration of the impurity in the p-type semiconductor layer 65p originating from the ion implantation in the first step is in a range from about 7×10¹⁶ cm⁻³ to 2×10¹⁷ cm⁻³. In the ion implantation in a second step, the range Rp of the impurity from the surface of the semiconductor substrate 60 is in a range from 500 nm to 700 nm. The peak concentration of the impurity in the p-type semiconductor layer 65p originating from the ion implantation in the second step is in a range from about 1×10¹⁶ cm⁻³ to 5×10¹⁶ cm⁻³.

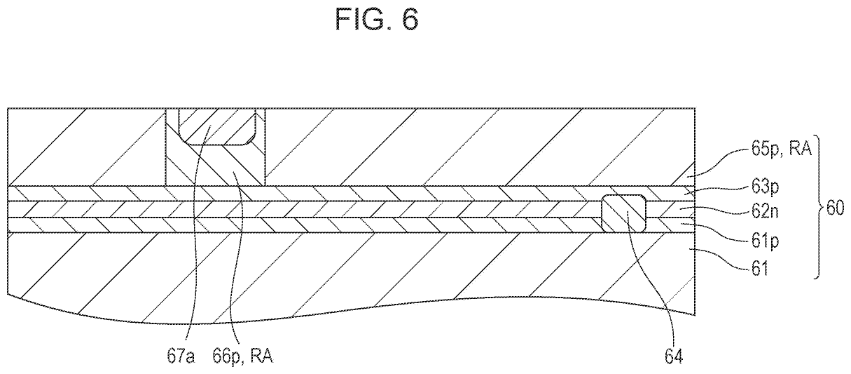

In FIG. 6, the first region 67a of the n-type impurity region 67n is formed by photolithography and ion implantation. The n-type impurity to be implanted is arsenic. In the ion implantation, the range Rp of the impurity from the surface of the semiconductor substrate 60 is in a range from 50 nm to 100 nm. The peak concentration of the impurity in the first region 67a of the n-type impurity region 67n is in a range from about 1×10¹⁷ cm⁻³ to 5×10¹⁷ cm⁻³. As mentioned above, the n-type impurity region 67n is either the source or the drain of the reset transistor 26.

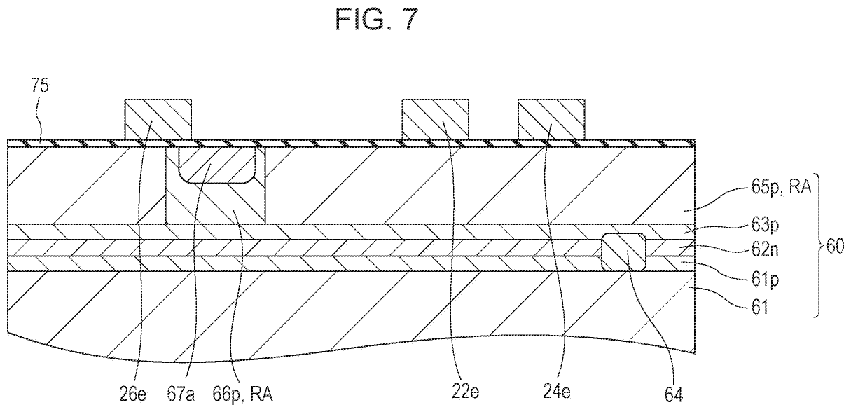

In FIG. 7, the fifth insulating layer 75 is formed in accordance with a process such as an in situ steam generation (ISSG) process. The fifth insulating layer 75 is a gate oxide film. A thickness of the fifth insulating layer 75 is in a range from about 7 nm to 10 nm.

In FIG. 7, the gate electrode 22e, the gate electrode 24e, and the gate electrode 26e are formed on the fifth insulating layer 75. These gate electrodes 22e, 24e, and 26e are formed by using a polysilicon material. A high concentration of an n-type impurity originating from ion implantation is present in this polysilicon material. A film of the polysilicon material in a thickness from about 100 nm to 200 nm is formed on the fifth insulating layer 75. This film is processed by photolithography and dry etching. In this way, the gate electrodes 22e, 24e, and 26e are formed. The gate electrodes 22e, 24e, and 26e are provided with conductivity as a consequence of reduction in resistance by use of the n-type impurity.

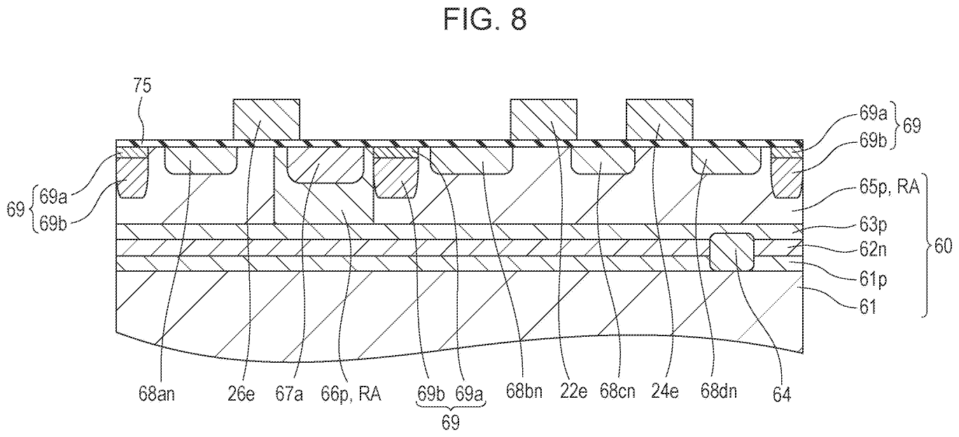

In FIG. 8, the specific region 69a and the element isolation region 69b of the shield structure 69 are formed by photolithography and ion implantation.

The ion implantation of the element isolation region 69b takes place in multiple steps. Specifically, this ion implantation takes place in two steps. The p-type impurity to be implanted is boron. In the ion implantation in a first step, the range Rp of the impurity from the surface of the semiconductor substrate 60 is in a range from 20 nm to 50 nm. The peak concentration of the impurity in the element isolation region 69b originating from the ion implantation in the first step is in a range from about 1×10¹⁸ cm⁻³ to 3×10¹⁸ cm⁻³. In the ion implantation in a second step, the range Rp of the impurity from the surface of the semiconductor substrate 60 is in a range from 120 nm to 180 nm. The peak concentration of the impurity in the element isolation region 69b originating from the ion implantation in the second step is in a range from about 3×10¹⁷ cm⁻³ to 6×10¹⁷ cm⁻³.

In the ion implantation of the specific region 69a, the n-type impurity to be implanted is phosphorus. In the ion implantation, the range Rp of the impurity from the surface of the semiconductor substrate 60 is in a range from 2 nm to 10 nm. The peak concentration of the impurity in the specific region 69a is in a range from about 1×10¹⁹ cm⁻³ to 5×10¹⁹ cm⁻³.

In FIG. 8, the n-type impurity region 68an, the n-type impurity region 68bn, the n-type impurity region 68cn, and the n-type impurity region 68dn are formed by photolithography and ion implantation. In the ion implantation of the n-type impurity regions 68an, 68bn, 68cn, and 68dn, the n-type impurity to be implanted is arsenic. In the ion implantation of these regions, the range Rp of the impurity from the surface of the semiconductor substrate 60 is in a range from 10 nm to 30 nm. The peak concentration of the impurity in each of the n-type impurity regions 68an, 68bn, 68cn, and 68dn is in a range from about 5×10¹⁹ cm⁻³ to 9×10¹⁹ cm⁻³. As mentioned above, each of the n-type impurity regions 68an, 68bn, 68cn, and 68dn is either the source or the drain of the corresponding transistor.

The order of formation of the shield structure 69, the n-type impurity region 68an, the n-type impurity region 68bn, the n-type impurity region 68cn, and the n-type impurity region 68dn is not limited to a particular order.

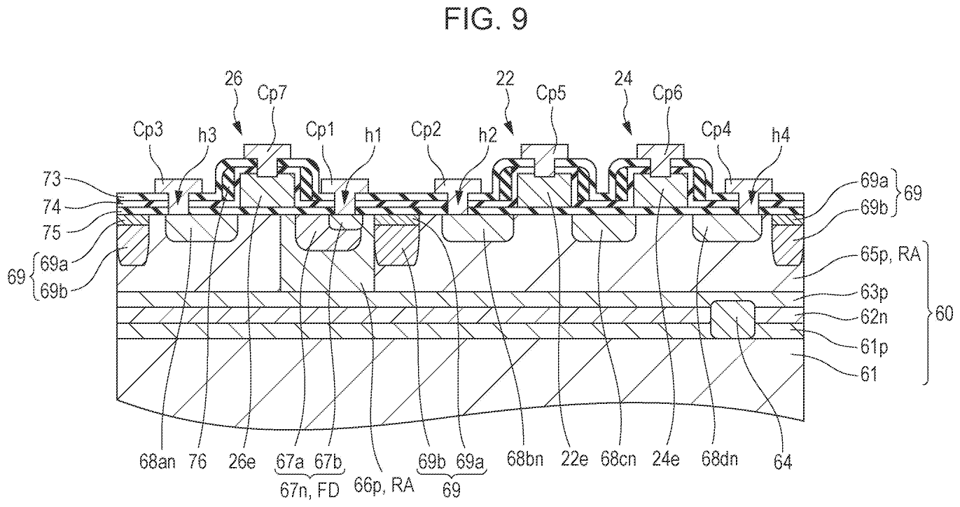

In FIG. 9, the contact plugs Cp1 to Cp7 are doped with phosphorus at a high concentration as mentioned above. To be more precise, the contact plugs Cp1 to Cp7 are formed by processing a film that is obtained by depositing materials thereof. The film contains phosphorus at the concentration in a range from about 6×10²⁰ cm⁻³ to 8×10²⁰ cm⁻³ at a point immediately after the film deposition. Following the formation of the contact plugs Cp1 to Cp7, phosphorus in the contact plugs Cp1 to Cp7 is activated by conducting a thermal treatment at a temperature higher than or equal to 800° C. This activation reduces the concentration of phosphorus in the contact plugs Cp1 to Cp7 to a range from 5×10²⁰ cm⁻³ to 6×10²⁰ cm⁻³ due to outward diffusion caused by the thermal treatment. Meanwhile, due to the heat at the time of the thermal treatment, phosphorus in the contact plugs Cp1, Cp3, Cp2, and Cp4 is diffused to the n-type impurity region 67n, the n-type impurity region 68an, the n-type impurity region 68bn, and the n-type impurity region 68dn, respectively. Thus, the second regions having the high impurity concentration are formed in the n-type impurity region 67n, the n-type impurity region 68an, the n-type impurity region 68bn, and the n-type impurity region 68dn. Each second region is the n⁺-type impurity region.

Back to FIG. 3, the configuration of the imaging device 100 will be described further.

Insulating layers are disposed on the surface of the semiconductor substrate 60 on the photoelectric conversion structure 12A side. In this example, the surface of the semiconductor substrate 60 on the photoelectric conversion structure 12A side is covered with the first insulating layer 71, the second insulating layer 72, the third insulating layer 73, the fourth insulating layer 74, and the fifth insulating layer 75. The fifth insulating layer 75 is a gate insulating layer. The fifth insulating layer 75 is a gate oxide film in a typical example.

In the present embodiment, each of the first insulating layer 71, the third insulating layer 73, the fourth insulating layer 74, and the fifth insulating layer 75 contains a silicon oxide. To be more precise, each of the first insulating layer 71, the third insulating layer 73, the fourth insulating layer 74, and the fifth insulating layer 75 contains silicon dioxide. The second insulating layer 72 contains a silicon nitride.

The fourth insulating layer 74 is provided on the fifth insulating layer 75. Meanwhile, the gate electrode 22e, the gate electrode 24e, and the gate electrode 26e are provided on the fifth insulating layer 75.

A sixth insulating layer 76 is provided on sidewall portions of the gate electrodes 22e, 24e, and 26e with a portion of the fourth insulating layer 74 disposed in between. Each sixth insulating layer 76 is a sidewall spacer. The sixth insulating layer 76 is also referred to as a sidewall.

In the present embodiment, the sixth insulating layer 76 has a laminated structure including two or more insulating layers. In one example, the sixth insulating layer 76 includes a silicon dioxide layer and a silicon nitride layer.

The fourth insulating layer 74 is an offset sidewall spacer. The offset sidewall spacer is also referred to as an offset sidewall. The fourth insulating layer 74 is used for reducing overlap capacitance for enhancing a circuit speed of each transistor at the time of formation of the transistors in the peripheral circuits 40. Moreover, the fourth insulating layer 74 is used for improving a short channel effect of each transistor due to the thermal treatment using a furnace which is a diffusion furnace.

As illustrated in FIG. 3, the third insulating layer 73, the fourth insulating layer 74, and the fifth insulating layer 75 are laminated on one another. The laminated structure of the third insulating layer 73, the fourth insulating layer 74, and the fifth insulating layer 75 is provided with a contact hole h1, a contact hole h2, a contact hole h3, and a contact hole h4. In other words, each of the contact hole h1, the contact hole h2, the contact hole h3, and the contact hole h4 is in contact with the semiconductor substrate 60 through the laminated structure of the third insulating layer 73, the fourth insulating layer 74, and the fifth insulating layer 75.

In the example illustrated in FIG. 3, the contact hole h1 is provided on the n-type impurity region 67n. To be more precise, the contact hole h1 is provided on the second region 67b, which is the n⁺-type impurity region.

In the example illustrated in FIG. 3, the contact hole h2 is provided on the n-type impurity region 68bn. The contact hole h3 is provided on the n-type impurity region 68an. The contact hole h4 is provided on the n-type impurity region 68dn.

Each of the contact plugs Cp1 to Cp7 is a non-silicide, the entirety of which is formed substantially from polysilicon. Each of the contact plugs Cp1 to Cp7 contains the n-type impurity. In the present embodiment, each of the contact plugs Cp1 to Cp7 includes a non-silicide surface. In the present embodiment, each of the contact plugs Cp1 to Cp7 contains phosphorus as the impurity.

Here, the silicide is a compound of a metal and silicon. Here, the silicon is a concept that encompasses polysilicon. The non-silicide contact plug includes substantially no silicide region. In one example, the entirety of the non-silicide contact plug is substantially formed from silicon. In one specific example, the entirety of the non-silicide contact plug is substantially formed from polysilicon. The non-silicide surface substantially includes no silicide region. In one example, the entirety of the non-silicide surface is substantially formed from silicon. In one specific example, the entirety of the non-silicide surface is substantially formed from polysilicon. In this context, the expression “includes substantially no silicide region” means that the content of the silicide relative to the total is lower than 10% by mass. This content is typically lower than 5% by mass, or this content may be equal to 0% by mass. The expression “is substantially formed from silicon” means that the content of silicon relative to the total is higher than or equal to 90% by mass. This content is typically higher than or equal to 95% by mass, or this content may be equal to 100% by mass. The same applies to the expression “is substantially formed from polysilicon”. In one specific example, the silicide is formed in the peripheral region R2.

In the present embodiment, the non-silicide surfaces of the contact plugs Cp1 to Cp7 are in contact with the via plugs 88. Further, the non-silicide surfaces of the contact plugs Cp1 to Cp7 are in contact with portions of the first insulating layer 71 located above the contact plugs Cp1 to Cp7. Here, a portion above the contact plug means an opposite side from the semiconductor substrate 60 when viewed from the contact plug.

In the example illustrated in FIG. 3, the contact plug Cp1 couples the conducting structure 89 to the n-type impurity region 67n while passing through the contact hole h1. To be more precise, the contact plug Cp1 couples the conducting structure 89 to the second region 67b being the n⁺-type impurity region while passing through the contact hole h1. Thus, the n-type impurity region 67n is electrically coupled to the pixel electrode 12a of the photoelectric converter 12 through the contact plug Cp1 and the conducting structure 89. In this example, the n-type impurity region 67n is the charge accumulation region FD. The signal charges generated by the photoelectric converter 12 are accumulated in the n-type impurity region 67n.

As described above, in the present embodiment, the impurity in the second region 67b is introduced by the diffusion from the contact plug Cp1. To be more precise, the impurity in the second region 67b is introduced by the diffusion from the contact plug Cp1 during the thermal treatment at the time of manufacturing the imaging device 100. Accordingly, the second region 67b contains the impurity of the same composition as that of the impurity in the contact plug Cp1. In the present embodiment, this impurity is phosphorus.

The concentration of this impurity is high in the second region 67b. Contact resistance between the n-type impurity region 67n and the contact plug Cp1 is reduced by this high impurity concentration. The impurity concentration of the second region 67b is about 5×10²⁰ cm⁻³, for example.

The semiconductor substrate 60 is provided with the signal detection circuit 14A. As described above, the signal detection circuit 14A includes the signal detection transistor 22, the address transistor 24, and the reset transistor 26.

The signal detection transistor 22 includes the n-type impurity region 68bn as one of the source and the drain. The signal detection transistor 22 includes the n-type impurity region 68cn as the other one of the source and the drain. The signal detection transistor 22 further includes the gate electrode 22e. The gate electrode 22e is provided on the fifth insulating layer 75. A portion of the fifth insulating layer 75 located between the gate electrode 22e and the semiconductor substrate 60 functions as a gate insulating layer of the signal detection transistor 22. The gate electrode 22e is coupled to the pixel electrode 12a and the n-type impurity region 67n through the contact plug Cp5 and the conducting structure 89. In a layer where the address signal line 34 and the reset signal line 36 are located, the gate electrode 22e is coupled to a portion 39 of the conducting structure 89 to couple the pixel electrode 12a and the contact plug Cp5 to each other.

The contact plug Cp2 is coupled to the n-type impurity region 68bn. Part of the contact plug Cp2 is provided inside the contact hole h2. The power supply line 32 serving as a source follower power supply is electrically coupled to the contact plug Cp2. Note that illustration of the power supply line 32 is omitted in FIG. 3.

The address transistor 24 includes the n-type impurity region 68cn as one of the source and the drain. The address transistor 24 includes the n-type impurity region 68dn as the other one of the source and the drain. The address transistor 24 further includes the gate electrode 24e. The gate electrode 24e is provided on the fifth insulating layer 75. A portion of the fifth insulating layer 75 located between the gate electrode 24e and the semiconductor substrate 60 functions as a gate insulating layer of the address transistor 24. The address signal line 34 is coupled to the gate electrode 24e through the contact plug Cp6 and the conducting structure 89. In this example, the n-type impurity region 68cn is shared between the address transistor 24 and the signal detection transistor 22. Thus, these transistors are electrically coupled to each other.

The contact plug Cp4 is coupled to the n-type impurity region 68dn. Part of the contact plug Cp4 is provided inside the contact hole h4. The contact plug Cp4 is electrically coupled to the vertical signal line 35.

The reset transistor 26 includes the n-type impurity region 67n as one of the source and the drain. The reset transistor 26 includes the n-type impurity region 68an as the other one of the source and the drain. In the illustrated example, one of the source and the drain of the reset transistor 26 is the n-type charge accumulation region FD. The reset transistor 26 further includes the gate electrode 26e. The gate electrode 26e is provided on the fifth insulating layer 75. A portion of the fifth insulating layer 75 located between the gate electrode 26e and the semiconductor substrate 60 functions as a gate insulating layer of the reset transistor 26. The reset signal line 36 is coupled to the gate electrode 26e through the contact plug Cp7 and the conducting structure 89.

As illustrated in FIG. 3, the n-type impurity region 68an is coupled to the contact plug Cp3. Part of the contact plug Cp3 is provided inside the contact hole h3. The contact plug Cp3 is electrically coupled to the feedback line 53 through the conducting structure 89.

Next, a description will be given concerning the first insulating layer 71, the second insulating layer 72, and the third insulating layer 73.

The first insulating layer 71 is in contact with the upper surfaces and side surfaces of the contact plugs Cp1 to Cp7. The gate electrode 22e, the contact plug Cp5, and the first insulating layer 71 are laminated in this order. The gate electrode 24e, the contact plug Cp6, and the first insulating layer 71 are laminated in this order. The gate electrode 26e, the contact plug Cp7, and the first insulating layer 71 are laminated in this order.

The first insulating layer 71 has a function to suppress diffusion of the impurity from the inside to the outside of each of the contact plugs Cp1 to Cp7. A thickness of the first insulating layer 71 in the imaging device 100 is greater than or equal to 10 nm and smaller than or equal to 15 nm, for example. The above-described function can be ensured by setting the thickness as mentioned above.

In the present embodiment, the silicide is formed by introducing the metal into the peripheral circuits 40 in the course of manufacturing the imaging device 100. In this silicide formation process, the metal is introduced not only into the peripheral region R2 but also into the imaging region R1 in a typical example. The first insulating layer 71 fulfills a function as a silicide block that prevents the metal introduced into the imaging region R1 in the silicide formation process from being in contact with the contact plugs Cp1 to Cp1. The silicide block function can be fulfilled when the thickness of the first insulating layer 71 is greater than or equal to 10 nm and smaller than or equal to 15 nm. It is also possible to reduce a global step in the peripheral region R2 and the imaging region R1 when the thickness of the first insulating layer 71 is in this range.

The second insulating layer 72 includes the silicon nitride. The second insulating layer 72 functions as an etching stopper at the time of formation of the seventh insulating layer 91. A thickness of the second insulating layer 72 is greater than or equal to 30 nm and smaller than or equal to 50 nm, for example. The second insulating layer 72 can suppress parasitic capacitance while ensuring the function as the etching stopper when its thickness is in this range.

The seventh insulating layer 91 is part of the interlayer insulating layer 90. The seventh insulating layer 91 contains silicon dioxide. A thickness of the seventh insulating layer 91 is in a range from about 300 nm to 600 nm, for example.

The seventh insulating layer 91 is provided with the coupling holes 88h. The coupling holes 88h are formed by photolithography and dry etching. A conductive metal is embedded in the coupling holes 88h. This conductive metal constitutes the via plugs 88. The conductive metal is tungsten (W), for example. The via plugs 88 are coupled to the pixel electrode 12a through the metal wiring 87.

The third insulating layer 73 contains silicon dioxide. When at least part of the third insulating layer 73 is present between two constituents, the third insulating layer 73 can ensure a dielectric strength voltage between these constituents.

Through holes are provided at portions of the third insulating layer 73, the fourth insulating layer 74, and the fifth insulating layer 75 above the sources and drains of the transistors in the signal detection circuit 14A. Some of these through holes correspond to the contact holes h1 to h4. The through holes can be formed by photolithography and dry etching. A diameter of each through hole is in a range from 80 nm to 100 nm, for example.

Through holes are also provided above the gate electrodes of the transistors in the signal detection circuit 14A. These through holes can also be formed by photolithography and dry etching.

Part of the contact plug Cp1 is provided inside the through hole. The same applies to the contact plugs Cp2 to Cp7. The contact plugs Cp1 to Cp7 can be formed as follows. Specifically, after formation of the through holes, a phosphorus-doped polysilicon growth process is carried out. Thus, a film in a thickness of about 100 nm is deposited, for example. Next, this deposited film is partially removed. In this way, the contact plugs Cp1 to Cp7 are formed.

The impurity contained in the contact plugs Cp1 to Cp7 is activated by the thermal treatment. As described above, the impurity is phosphorus in the present embodiment. Since the impurity is activated, each of the contact plugs Cp1 to Cp7 has low resistance. This is due to the following reason. Specifically, the impurity is captured by crystals inside the polysilicon grain boundary so that the impurity can act as carriers easily. The thermal treatment is carried out at a temperature higher than or equal to 800° C. and in a nitrogen atmosphere by using a diffusion furnace, for example.

As described above, when the contact plug Cp1 reaches a high temperature as a consequence of the thermal treatment, the impurity inside the contact plug Cp1 is diffused to the second region 67b of the n-type impurity region 67n. In this way, the impurity concentration is increased in a partial region of the n-type impurity region 67n. The region with the concentration of the impurity thus increased is the second region 67b being the n-type impurity region. The same impurity diffusion also takes place between each of the contact plugs Cp2 to Cp4 and the corresponding one of the n-type impurity regions 68bn, 68an, and 68dn coupled thereto. Moreover, the thermal treatment also performs an action to recover from crystal defects attributed to damage caused at the time of the ion implantation into the n-type impurity region 67n and at the time of the dry etching.

A further description will be given below of a configuration in the vicinity of the reset transistor 26.

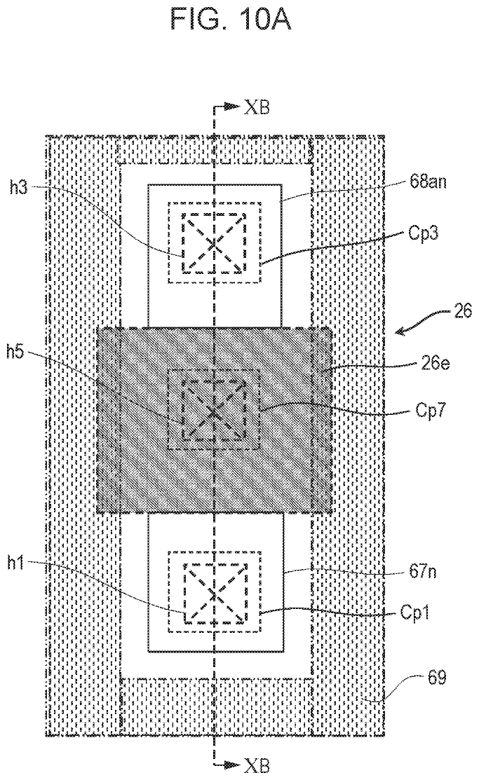

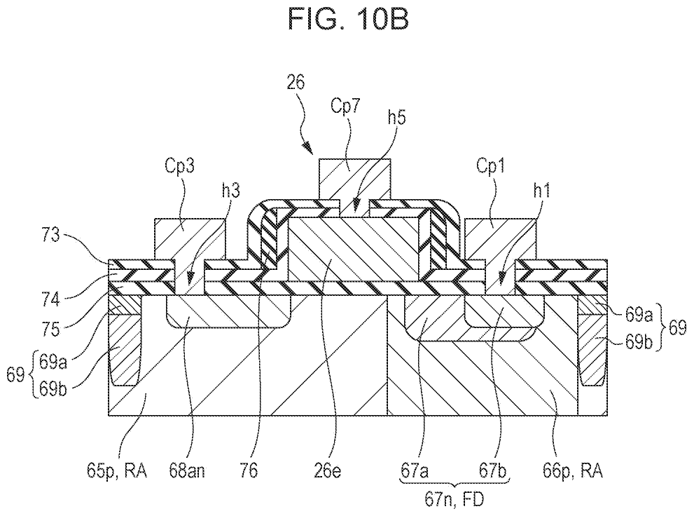

FIG. 10A is an enlarged layout diagram of a portion in the vicinity of the reset transistor 26 in the present embodiment. FIG. 10B is an enlarged sectional view of the portion in the vicinity of the reset transistor 26 in the present embodiment. To be more precise, FIG. 10B is a sectional view taken along the XB-XB line in FIG. 10A.

As understood from FIG. 10A, the shield structure 69 is located away from the n-type impurity region 67n in plan view. In other words, the shield structure 69 is not in contact with the n-type impurity region 67n. To be more precise, the p-type semiconductor layer 66p is interposed between the n-typed specific region 69a and the n-type impurity region 67n. A p-n junction between the specific region 69a and the p-type semiconductor layer 66p and the p-n junction between the p-type semiconductor layer 66p and the n-type impurity region 67n are thus formed.

In plan view, the shield structure 69 partially overlaps the gate electrode 26e. The contact plug Cp1 is coupled to the gate electrode 26e while passing through a contact hole h5.

As understood from FIG. 10B, the second region 67b is not completely surrounded by the first region 67a in plan view. There are provided not only the p-n junction between the p-type semiconductor layer 66p and the first region 67a, but also the p-n junction between the second region 67b and the p-type semiconductor layer 66p. The p-n junction between the second region 67b and the p-type semiconductor layer 66p faces the specific region 69a while interposing the p-type semiconductor layer 66p in between. To be more precise, these features are observed in the vicinity of the surface of the semiconductor substrate 60.

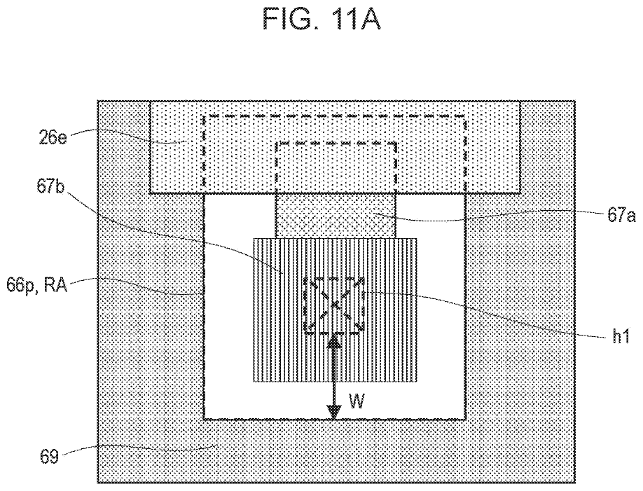

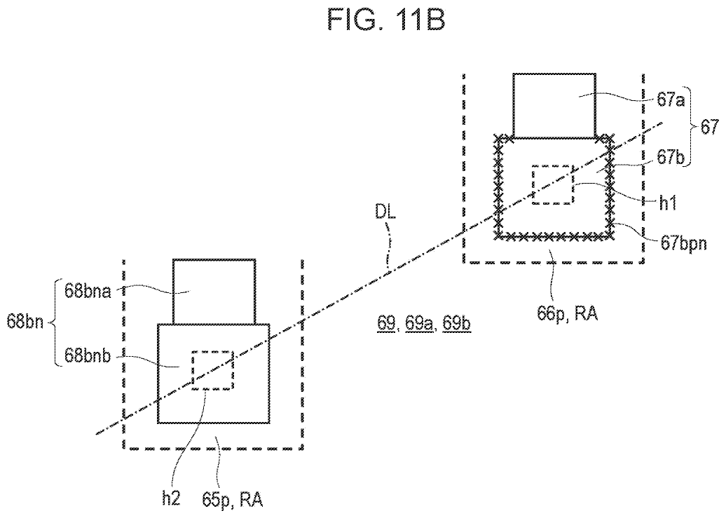

FIG. 11A is an enlarged layout diagram of a portion in the vicinity of the n-type impurity region 67n in the present embodiment. In FIG. 11A, an opening of a mask used at the time of formation of the contact hole h1 is schematically drawn with dashed lines inside hatching that indicates the second region 67b. The opening of the mask is a rectangle with each side at a length of 80 nm to 100 nm in plan view. Note that the contact hole h1 to be actually formed is rounded.

The contact plug Cp1 is coupled to the n-type impurity region 67n through the contact hole h1. As described above, the impurity in the contact plug Cp1 is diffused from the contact plug Cp1 to the n-type impurity region 67n as a consequence of the thermal treatment in the course of manufacturing the imaging device 100. Hence, the second region 67b is formed. The impurity is phosphorus in the present embodiment. The n-type impurity region 67n corresponds to the charge accumulation region FD.

As understood from FIG. 11A, the diffusion of the impurity constituting the second region 67b in the direction of the shield structure 69 remains within an appropriate range. The second region 67b is not diffused to the shield structure 69. To be more precise, the p-type semiconductor layer 66p is interposed between the second region 67b and the specific region 69a, and the second region 67b does not reach the p-n junction between the specific region 69a and the p-type semiconductor layer 66p. For this reason, a dielectric withstanding voltage is likely to be ensured between the charge accumulation region FD and the shield structure 69. To be more precise, even when a potential difference is generated between the charge accumulation region FD and the shield structure 69, the charges in the specific region 69a of the shield structure 69 are less likely to flow into the charge accumulation region FD. Here, an outer edge of the second region 67b indicates a portion where the impurity concentration is equal to 1×10¹⁶ cm 3.

Here, the range of diffusion of the impurity from the contact plug Cp1 depends on conditions of the thermal treatment. In the present embodiment, the impurity in the contact plug Cp1 is diffused in a range at a distance of about 80 nm to 120 nm from an end of the contact hole h1. In other words, the second region 67b spreads to this range. Here, the outer edge of the second region 67b indicates the portion where the impurity concentration is equal to 1×10¹⁶ cm⁻³.

As understood from FIG. 11A, the p-type semiconductor layer 66p surrounds the first region 67a and the second region 67b in plan view. The p-type semiconductor layer 66p partially overlaps the gate electrode 26e in plan view. The first region 67a partially overlaps the gate electrode 26e in plan view.

A p-n junction 67bpn is formed between the second region 67b and the p-type semiconductor layer 66p. FIG. 11B is a layout diagram for describing positional relations among the first contact hole h1, the p-n junction 67bpn, the element isolation region 69b, and the second contact hole h2. In FIG. 11B, the p-n junction 67bpn is schematically illustrated by using “x” marks. FIG. 11B illustrates a first region 68bna of the n-type impurity region 68bn and a second region 68bnb of the n-type impurity region 68bn. Illustration of the gate electrode 22e, the gate electrode 26e, and the like is omitted in FIG. 11B.

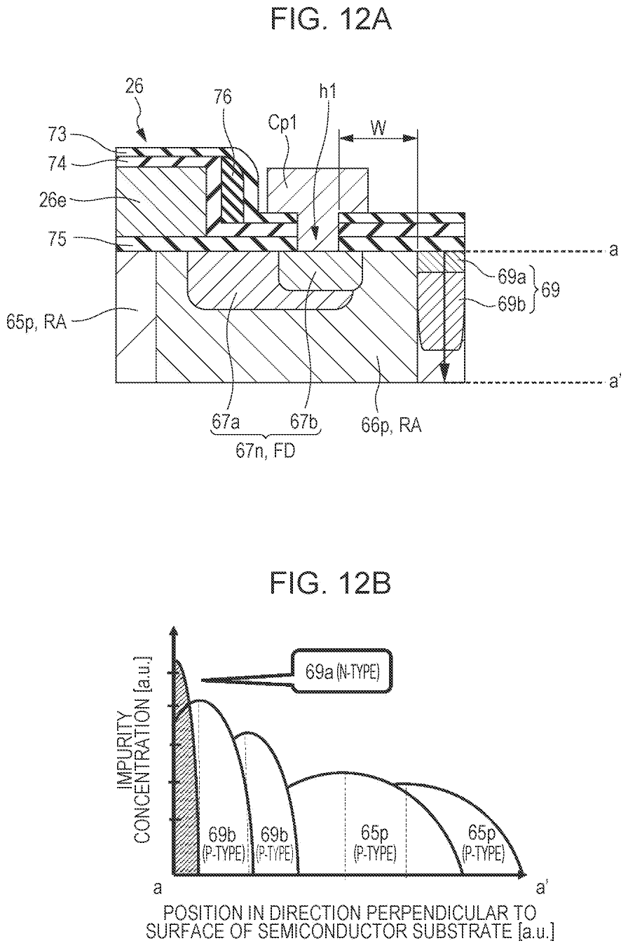

FIG. 12A is a sectional view of the portion in the vicinity of the reset transistor 26 in the embodiment. FIG. 12B is a graph illustrating distribution of impurity concentrations in a direction perpendicular to the surface of the semiconductor substrate 60 in the present embodiment. To be more precise, FIG. 12B illustrates the distribution of the impurity concentrations along the a-a′ line in FIG. 12A. The a-a′ line extends in the shield structure 69. The horizontal axis of FIG. 12B indicates the position in the direction perpendicular to the surface of the semiconductor substrate 60. The vertical axis of FIG. 12B indicates the impurity concentration.

The range Rp of the specific region 69a, the range Rp of the element isolation region 69b, and the range Rp of the p-type semiconductor layer 65p appear along the a-a′ line in this order from the surface of the semiconductor substrate 60. A depth where the impurity concentration of the specific region 69a reaches a peak value is smaller than a depth where the impurity concentration of the element isolation region 69b reaches a peak value and is smaller than a depth where the impurity concentration of the p-type semiconductor layer 65p reaches a peak value. The peak concentration of the specific region 69a is higher by about one digit than the peak concentration of the element isolation region 69b. To be more precise, the peak concentration of the specific region 69a is greater than or equal to 1×10¹⁹ cm⁻³.

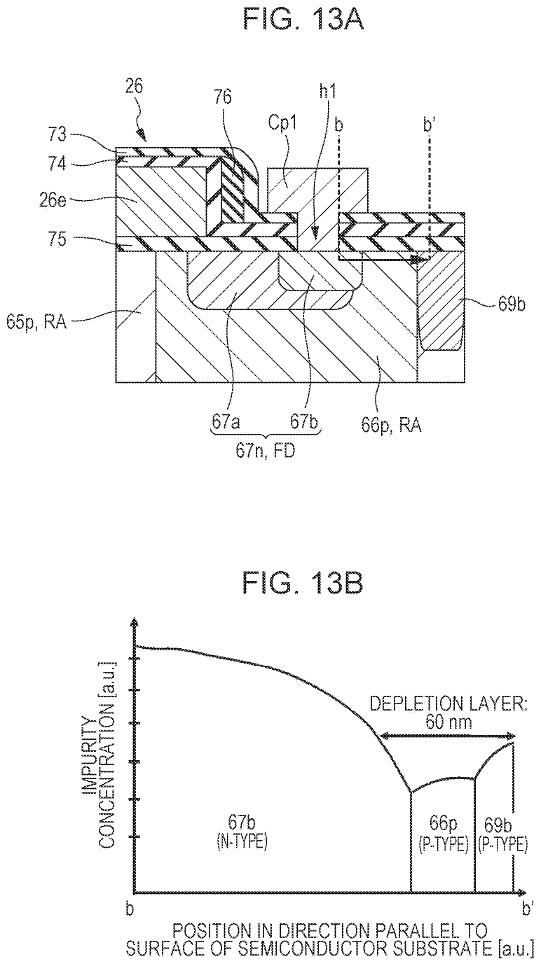

FIG. 13A is a sectional view of a portion in the vicinity of the reset transistor 26 in a referential mode. FIG. 13B is a graph illustrating distribution of impurity concentrations in a direction parallel to the surface of the semiconductor substrate 60 in the referential mode. To be more precise, FIG. 13B illustrates the distribution of the impurity concentrations along the b-b′ line in FIG. 13A. The b-b′ line extends in the second region 67b, the p-type semiconductor layer 66p, and the element isolation region 69b. The b-b′ line extends in the vicinity of the surface of the semiconductor substrate 60, or more specifically, at a position having a depth of 1 nm from the surface of the semiconductor substrate 60. The horizontal axis of FIG. 13B indicates the position in the direction parallel to the surface of the semiconductor substrate 60. The vertical axis of FIG. 13B indicates the impurity concentration.

In the referential mode, the shield structure 69 does not include the specific region 69a. To be more precise, the shield structure 69 consists of the element isolation region 69b.

In the referential mode, a p-n junction is formed between the second region 67b and the p-type semiconductor layer 66p. A depletion layer is generated in the vicinity of this p-n junction. To be more precise, in the referential mode, the depletion layer spreads into the shield structure 69. A leakage current may occur when the depletion layer is in contact with the surface of the semiconductor substrate 60.

A width of the depletion layer can be calculated by using the following formula 1:

Width of depletion layer=√{(2×ε0×εSi×(Vbi−V)/(q×Na)} (formula 1).

Here, ε0 represents permittivity of vacuum, εSi represents relative permittivity of silicon, V represents bias voltage (note that the bias voltage V is positive in the case of forward bias and the bias voltage V is negative in the case of reverse bias), Vbi represents built-in voltage, q represents elementary charge, and Na represents the impurity concentration of the p-type semiconductor layer 66p, respectively.

Under the condition of Na=2×10¹⁶ cm⁻³, the width of the depletion layer according to the referential mode calculated based on the formula 1 is about 60 nm.

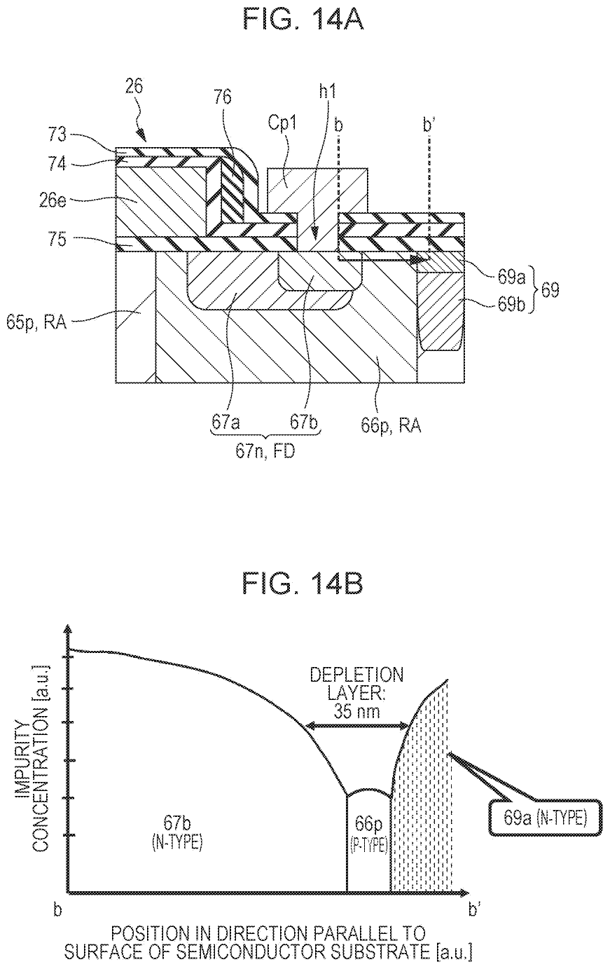

FIG. 14A is a sectional view of the portion in the vicinity of the reset transistor 26 in the embodiment. FIG. 14B is a graph illustrating distribution of impurity concentrations in the direction parallel to the surface of the semiconductor substrate 60 in the present embodiment. To be more precise, FIG. 14B illustrates the distribution of the impurity concentrations along the b-b′ line in FIG. 14A. The b-b′ line extends in the second region 67b, the p-type semiconductor layer 66p, and the specific region 69a. The b-b′ line extends in the vicinity of the surface of the semiconductor substrate 60, or more specifically, at a position having a depth of 1 nm from the surface of the semiconductor substrate 60. The horizontal axis of FIG. 14B indicates the position in the direction parallel to the surface of the semiconductor substrate 60. The vertical axis of FIG. 14B indicates the impurity concentration.

In the present embodiment, the shield structure 69 includes the specific region 69a and the element isolation region 69b.

A p-n junction is formed between the second region 67b and the p-type semiconductor layer 66p in this embodiment as well. Another p-n junction is also formed between the p-type semiconductor layer 66p and the specific region 69a. A depletion layer is generated in the vicinity of these p-n junctions. However, in the present embodiment, the depletion layer does not spread into the shield structure 69 because of the contribution of the specific region 69a. In other words, the spread of the depletion layer remains within a small range in the shield structure 69 as compared to the referential mode. In particular, the impurity concentration of the specific region 69a is higher than the impurity concentration of the p-type semiconductor layer 66p in the present embodiment. In this case, it is particularly easy to obtain a state where the depletion layer does not spread into the shield structure 69 or a state where the spread of the depletion layer remains within a small range in the shield structure 69.

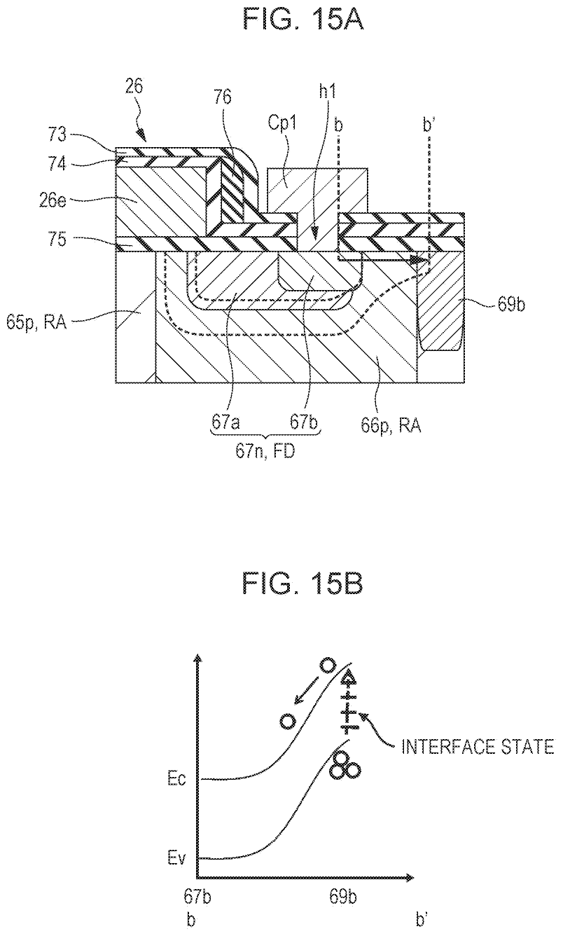

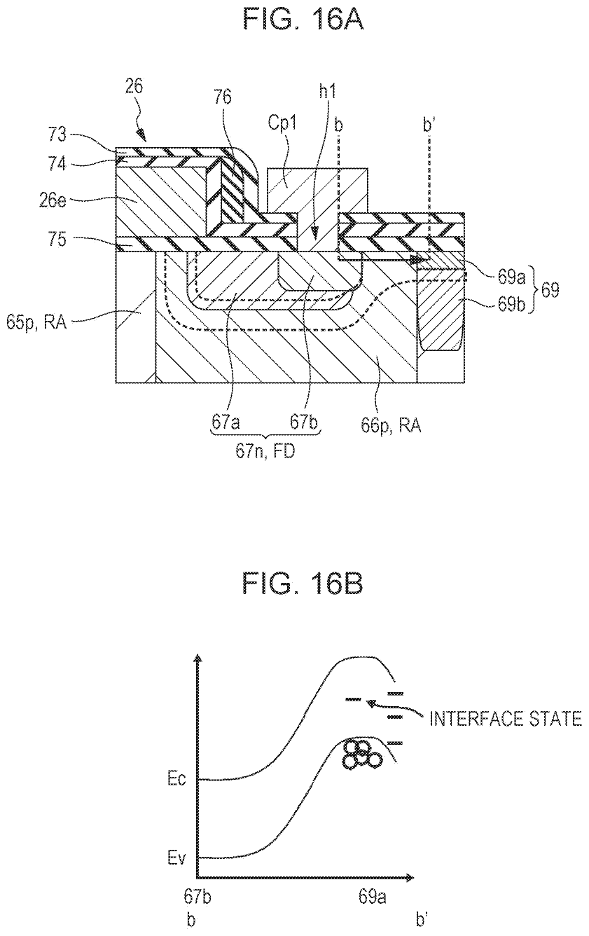

Due to the above-mentioned reasons, the present embodiment can reduce the width of the depletion layer in contact with the surface of the semiconductor substrate 60 as compared to the referential mode. This configuration can suppress a leakage current. In one example, the width of the depletion layer corresponds to a distance from the p-n junction between the second region 67b and the p-type semiconductor layer 66p to the p-n junction between the p-type semiconductor layer 66p and the specific region 69a in plan view. Note that the depletion layer of the referential mode and the depletion layer of the present embodiment are schematically illustrated in FIGS. 15A and 16A to be described later.

In the present embodiment, the impurity concentration of the second region 67b is higher than the impurity concentration of the p-type semiconductor layer 66p. In this case, it is easy to obtain a state where the depletion layer does not spread into the second region 67b or a state where the spread of the depletion layer remains within a small range in the second region 67b. This configuration can also reduce the width of the depletion layer in contact with the surface of the semiconductor substrate 60, thereby suppressing a leakage current.

Under the condition of Na=2×10¹⁶ cm′, the width of the depletion layer according to the present embodiment calculated based on the formula 1 is about 35 nm. According to this calculation result, the width of the depletion layer of about 60 nm is reduced to about 35 nm because of the contribution of the specific region 69a.

The effect of suppression of the leakage current based on the specific region 69a can also be explained by using an energy level diagram.

FIG. 15A is a sectional view illustrating distribution of the depletion layer in the vicinity of the reset transistor 26 in the referential mode. FIG. 15A schematically illustrates the distribution of the depletion layer. To be more precise, a portion surrounded by dashed lines is a portion where the depletion layer is distributed. FIG. 15B is an energy level diagram of the charge accumulation region FD and the element isolation region 69b in the referential mode. To be more precise, FIG. 15B is the energy level diagram along the b-b′ line in FIG. 15A. The b-b′ line in FIG. 15A corresponds to the b-b′ line in FIG. 13A. In FIG. 15B, Ev represents a valence band and Ec represents a conductive band.

The depletion layer is generated by the p-n junction between the first region 67a and the p-type semiconductor layer 66p. The impurity concentration of the first region 67a is higher by about one digit as compared to the impurity concentration of the p-type semiconductor layer 66p. Accordingly, the depletion layer originating from this p-n junction spreads more toward the p-type semiconductor layer 66p side than toward the first region 67a side as illustrated in FIG. 15A.

The depletion layer is generated by the p-n junction between the second region 67b and the p-type semiconductor layer 66p. The impurity concentration of the second region 67b is higher by about four digits as compared to the impurity concentration of the p-type semiconductor layer 66p. Accordingly, the depletion layer originating from this p-n junction spreads more toward the p-type semiconductor layer 66p side than toward the second region 67b side as illustrated in FIG. 15A.

In the referential mode, the depletion layer spreads into the element isolation region 69b as illustrated in FIG. 15A. To explain this aspect with reference to FIG. 15B, it is assumed that holes being the charges in the element isolation region 69b are thermally excited from the valence band Ev to the conductive band Ec through an interface state on the surface of the semiconductor substrate 60, and thereafter are prone to flow into the n-type impurity region 67n. In other words, a leakage current is assumed to be generated in this way.

FIG. 16A is a sectional view illustrating distribution of the depletion layer in the vicinity of the reset transistor 26 in the present embodiment. FIG. 16A schematically illustrates the distribution of the depletion layer. To be more precise, a portion surrounded by dashed lines is a portion where the depletion layer is distributed. FIG. 16B is an energy level diagram of the charge accumulation region FD and the specific region 69a in the present embodiment. To be more precise, FIG. 16B is the energy level diagram along the b-b′ line in FIG. 16A. The b-b′ line in FIG. 16A corresponds to the b-b′ line in FIG. 14A.

The depletion layer is generated by the p-n junction between the second region 67b and the p-type semiconductor layer 66p. Accordingly, the depletion layer originating from this p-n junction spreads more toward the p-type semiconductor layer 66p side than toward the second region 67b side as illustrated in FIG. 16A. However, there is the specific region 69a in the present embodiment. For this reason, the spread of the depletion layer is suppressed. Particularly, in the present embodiment, the impurity concentration of the specific region 69a is higher by about three digits than the impurity concentration of the p-type semiconductor layer 66p. As a consequence, the spread of the depletion layer is particularly prone to be suppressed.

The depletion layer is generated by the p-n junction between the specific region 69a and the element isolation region 69b. However, in the present embodiment, the impurity concentration of the specific region 69a is higher than the impurity concentration of the element isolation region 69b. Accordingly, the depletion layer originating from this p-n junction spreads more toward the element isolation region 69b side than toward the specific region 69a side.

In the present embodiment, the depletion layer does not spread into the specific region 69a. In other words, the spread of the depletion layer remains within a small range in the specific region 69a. To be more precise, the depletion layer does not spread into the specific region 69a in the present embodiment as illustrated in FIG. 16A. As a consequence, the width of the depletion layer in contact with the surface of the semiconductor substrate 60 is smaller than that in the referential mode. To explain this aspect with reference to FIG. 16B, a level of the valence band of the element isolation region 69b is significantly distant from the interface state on the surface of the semiconductor substrate 60 because of the presence of the specific region 69a. For this reason, the holes being the charges in the element isolation region 69b are less likely to be thermally excited from the valence band Ev to the conductive band Ec through the interface state on the surface of the semiconductor substrate 60. As a consequence, the charges are less likely to flow into the n-type impurity region 67n. In this way, a leakage current can be suppressed.

Next, a description will be given of the depletion layer on the surface of the semiconductor substrate 60 of the present embodiment which involves the specific region 69a and the second region 67b. A potential difference between the specific region 69a and the second region 67b is about 0.5 V. That is to say, although the depletion layer generated by the p-n junction between the specific region 69a and the p-type semiconductor layer 66p is linked to the depletion layer generated by the p-n junction between the second region 67b and the p-type semiconductor layer 66p, this link does not bring about a so-called punch-through phenomenon. Specifically, there is a location in the p-type semiconductor layer 66p where the electric potential is high in the state where the depletion layer extending from the specific region 69a is linked to the depletion layer extending from the second region 67b. This location having the high potential functions as a barrier against the holes and no electric current flows therein. In other words, a punch-through phenomenon does not take place. The leakage current can be suppressed in this operating state.

### Test A

The present disclosure will be described below in further detail based on a test A. A term “distance W” is used in the description concerning the test A. The distance W is a distance between an end portion of the contact hole h1 and an end portion of the specific region 69a in plan view. In this context, the end portion of the specific region 69a is assumed to represent the p-n junction between the specific region 69a and the p-type semiconductor layer 66p. In other words, the distance W is a minimum distance between the contact hole h1 and the specific region 69a in plan view. The distance W is indicated in FIGS. 11A and 12A.

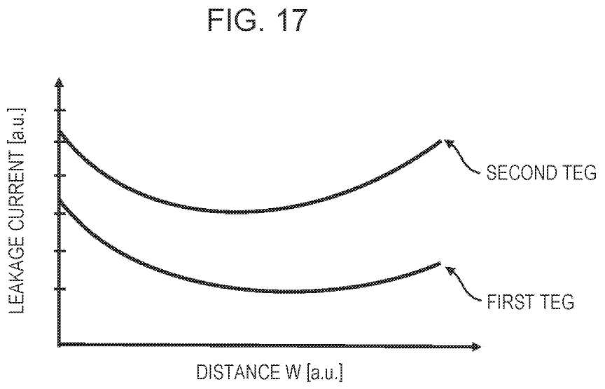

First test element groups (TEGs) were manufactured in such a way as to simulate part of the imaging device 100 according to the present embodiment. The distances W in these first TEGs vary with one another. Second TEGs were manufactured in such a way as to simulate part of the imaging device 100 according to the referential mode. The distances W in these second TEGs vary with one another. In the test A, a voltage at 0.5 V was applied to the charge accumulation regions FD of the first TEGs and the second TEGs, and leakage currents generated at the time of application of this voltage were measured. FIG. 17 is a graph illustrating results of the test A. The horizontal axis of FIG. 17 indicates the distance W, and the vertical axis thereof indicates the leakage current.

As illustrated in FIG. 17, a distance W-leakage current curve obtained by measuring the leakage currents on the first TEGs with various distances W has a similar shape to a distance W-leakage current curve obtained by measuring the leakage currents on the second TEGs with various distances W. Nonetheless, the leakage currents on the first TEGs were lower by about 20% to 30% than the leakage currents on the second TEGs at any values of the distances W. A reason why the leakage currents on the first TEGs are smaller is assumed to be due to the suppression of the spread of the depletion layer in the vicinity of the surface of the semiconductor substrate 60 because of the specific region 69a.

As understood from FIG. 17, the leakage current is increased when the distance W is reduced to be excessively short. The leakage current is also increased when the distance W is increased to be excessively long. The leakage current reaches a minimum value when the distance W has a certain value.

The increase in leakage current in the case of the excessively short distance W is thought to be attributed to an increase in leakage current based on band-to-band tunneling caused by an increase in field intensity. The distance W can be set to an appropriately large value in consideration thereof. The distance W may be set longer than or equal to 50 nm, for example. Setting the distance W as mentioned above can reduce the leakage current attributed to the field intensity, thereby contributing to obtaining an image at high image quality.

In the meantime, in the semiconductor substrate 60, the depletion layer is formed between the second region 67b of the charge accumulation region FD and the specific region 69a. In the following description, a portion of this depletion layer which spreads on the surface of the semiconductor substrate 60 will be referred to as an interface depletion layer. The increase in leakage current in the case of the excessively long distance W is considered attributable to an increase in area of the interface depletion layer.

The increase in leakage current in the case of the excessively long distance W depends on the concentration of phosphorus with which the contact plug Cp1 is doped and on diffusion of phosphorus from the contact plug Cp1 into the semiconductor substrate 60 due to the thermal treatment. Here, let us consider a case where the concentration of phosphorus contained in the contact plug Cp1 is in a range from 6×10²⁰ to 8×10²⁰ cm⁻³ and the thermal treatment is carried out over a certain period of time. The inventor analyzed as to how far the phosphorus is diffused into the semiconductor substrate 60 in this case in accordance with secondary ion mass spectrometry. To be more precise, a diffusion distance of the phosphorus from the end portion of the contact hole h1 in plan view was analyzed. This distance was about 80 nm when the temperature at the thermal treatment was set to 800° C. and the thermal treatment period was set to 10 minutes. The distance was about 150 nm when the temperature at the thermal treatment was set to 850° C. and the thermal treatment period was set to 10 minutes. The distance was about 220 nm when the temperature at the thermal treatment was set to 900° C. and the thermal treatment period was set to 10 minutes. Here, the outer edge of the region where phosphorus is present means the portion where the concentration of phosphorus is equal to 1×10¹⁶ cm⁻³.

The above-mentioned temperatures in the range from 800° C. to 900° C. were determined on the premise of the thermal treatment using the diffusion furnace. The thermal treatment using the diffusion furnace can be carried out in order to recover from crystal defects. A thermal treatment at a temperature higher than or equal to 950° C. is not realistic because the impurity concentrations of the transistors in the peripheral region R2 and the imaging region R1 may fluctuate due to thermal diffusion.

As understood from the above description, it is possible to enlarge the range of phosphorus diffusion by raising the temperature of the thermal treatment. In this way, it is possible to reduce the area of the interface depletion layer that is the portion at the interface where the carriers are practically absent, and to reduce the problem of the increase in leakage current in the case of the excessively long distance W. Nevertheless, it is realistic to set the temperature of the thermal treatment below 950° C. in light of ensuring performances of the transistors. From this point of view, the range of diffusion of phosphorus is practically restricted. It is possible to set an upper limit of the distance W in consideration of the restriction of the range of diffusion of phosphorus. The distance W can be set shorter than or equal to 500 nm, for example. Setting the distance W as mentioned above can reduce the leakage current attributed to the interface depletion layer and obtain an image at high image quality. Note that setting the distance W shorter than or equal to 500 nm is also advantageous from the viewpoint of realizing high pixel density while reducing the size of each pixel 10A. The distance W may be set shorter than or equal to 300 nm.

In the above description, the distance W is defined as the distance between the end portion of the contact hole h1 and the end portion of the specific region 69a in plan view. Instead, the distance W may be defined as a distance between an end portion of the second region 67b in the charge accumulation region FD and the end portion of the specific region 69a in plan view. That is to say, the distance W can also be defined as a minimum distance between the second region 67b of the charge accumulation region FD and the specific region 69a. The description concerning the distance W in this specification is also appropriate from technical perspectives even in the case of defining the distance W as mentioned above. In this context, the end portion of the second region 67b is assumed to represent the p-n junction between the second region 67b and the p-type semiconductor layer 66p.

A further description will be given of characteristics that can be provided to the imaging device 100. Terms including a first conductivity type, a second conductivity type, a reference region RA, a first impurity region, and a second impurity region will be used in the following description. The first conductivity type and the second conductivity type are of mutually opposite conductivity types. In other words, the first conductivity type is one of the p-type and the n-type while the second conductivity type is the other one of the p-type and the n-type. In the illustrated example, the reference region RA includes the p-type semiconductor layer 65p and the p-type semiconductor layer 66p. To be more precise, the reference region RA is a combination of the p-type semiconductor layer 65p and the p-type semiconductor layer 66p. In the following description, the “charge accumulation region FD” in the previous description can be translated into the “first impurity region” and the “n-type impurity region 68bn” therein can be translated into the “second impurity region”. Besides, any of the techniques concerning the previous description can be combined with a technique concerning the following description.

The semiconductor substrate 60 includes the reference region RA, the first impurity region, the second impurity region, and the element isolation region 69b. The reference region RA is a region that contains the impurity of the first conductivity type. The first impurity region and the second impurity region are located in the reference region RA. The first impurity region and the second impurity region are regions that contain the impurity of the second conductivity type.

The reference region RA includes a first portion and a second portion. The first impurity region is located in the first portion. The second impurity region is located in the second portion. The first portion and the second portion may be continuous to each other or away from each other. The expression “the first impurity region and the second impurity region are located in the reference region RA” is the expression that intends to encompass both a mode in which the first portion and the second portion are continuous to each other and a mode in which the first portion and the second portion are away from each other.

The element isolation region 69b is located between the first impurity region and the second impurity region in plan view. The element isolation region 69b is a region that contains the impurity of the first conductivity type. In this configuration, the element isolation region 69b can function as a potential barrier to block exchange of the charges between the first impurity region and the second impurity region. For this reason, this configuration can suppress the leakage current between the first impurity region and the second impurity region.

A description will be given of the expression “the element isolation region 69b is located between the first impurity region and the second impurity region in plan view” in the above-mentioned context. To be more precise, this expression means that a line segment connecting the first impurity region to the second impurity region extends into the element isolation region 69b in plan view.

The control circuit 46 applies a voltage to the second impurity region. In this configuration, an electric field is applied to the second impurity region as a consequence of applying the voltage to the second impurity region, and minority carriers may be generated as a consequence. However, the element isolation region 69b can function as the potential barrier that blocks the exchange of the charges between the first impurity region and the second impurity region. Accordingly, it is possible to suppress migration of the minority carriers from the second impurity region to the first impurity region. Thus, the leakage current between the first impurity region and the second impurity region can be suppressed. In the example of FIG. 1, the control circuit 46 can apply the voltage to the second impurity region by using a power supply in the peripheral circuits 40. The power supply may be included in the vertical scanning circuit 42.

The semiconductor substrate 60 includes the specific region 69a. In a perpendicular direction being perpendicular to the surface of the semiconductor substrate 60, the specific region 69a is located between the surface and the element isolation region 69b. The specific region 69a is the region that contains the impurity of the second conductivity type. According to this configuration, it is possible to reduce the depletion layer in the vicinity of the surface of the semiconductor substrate 60 as understood from the description with reference to FIGS. 12A to 16B. In this way, the leakage current between the first impurity region and the second impurity region can be suppressed. The suppression of the leakage current can contribute to obtaining an image at high image quality. Here, the leakage current may also be referred to as a dark current.

A description will be given of the expression “in the perpendicular direction being perpendicular to the surface of the semiconductor substrate 60, the specific region 69a is located between the surface and the element isolation region 69h” in the above-mentioned context. To be more precise, this expression means that a line segment connecting the surface of the semiconductor substrate 60 to the element isolation region 69b and extending in the perpendicular direction extends in the specific region 69a.

The specific region 69a is typically in contact with the surface of the semiconductor substrate 60.

The first impurity region is typically in contact with the surface of the semiconductor substrate 60. The second impurity region is in contact with the surface of the semiconductor substrate 60.

In a first example, the first impurity region is the charge accumulation region FD that accumulates the charges generated by the photoelectric conversion. The second impurity region is one of a source and a drain of a transistor. To be more precise, the second impurity region is one of the source and the drain of the signal detection transistor 22. In other words, the second impurity region is the n-type impurity region 68bn. The first impurity region and the second impurity region belong to the same pixel 10.

The leakage current in the charge accumulation region FD is likely to cause noise that deteriorates an obtained image in particular. In this regard, the first impurity region is the charge accumulation region FD in the first example. In this configuration, the specific region 69a can perform the function to suppress the leakage current in the charge accumulation region FD, and is likely to contribute particularly to improvement in image quality.

The first impurity region may belong to a certain pixel 10 while the second impurity region may belong to a pixel 10 adjacent to the former pixel 10. In a second example, the first impurity region is the n-type impurity region 68an in a certain pixel 10 while the second impurity region is the impurity region in a pixel 10 adjacent to the certain pixel 10. In a third example, the first impurity region is the n-type impurity region 68dn in a certain pixel 10 while the second impurity region is the impurity region in a pixel 10 adjacent to the certain pixel 10.

The reference region RA is disposed between the first impurity region and the specific region 69a in plan view. This configuration is advantageous from the viewpoint of avoiding conduction between the first impurity region and the specific region 69a.

The reference region RA is disposed between the first impurity region and the specific region 69a at the position with the depth of 1 nm from the surface of the semiconductor substrate 60. This configuration is advantageous from the viewpoint of avoiding conduction between the first impurity region and the specific region 69a. Here, a portion of the reference region RA located between the first impurity region and the specific region 69a will be defined as a first reference region. In this instance, a distance from a p-n junction between the first impurity region and the first reference region and a p-n junction between the first reference region and the specific region 69a at the position with the depth of 1 nm from the surface of the semiconductor substrate 60 is longer than or equal to 50 nm, for example.

The reference region RA is disposed between the second impurity region and the specific region 69a in plan view. This configuration is advantageous from the viewpoint of avoiding conduction between the second impurity region and the specific region 69a.

The reference region RA is disposed between the second impurity region and the specific region 69a at the position with the depth of 1 nm from the surface of the semiconductor substrate 60. This configuration is advantageous from the viewpoint of avoiding conduction between the second impurity region and the specific region 69a. Here, a portion of the reference region RA located between the second impurity region and the specific region 69a will be defined as a second reference region. In this instance, a distance from a p-n junction between the second impurity region and the second reference region and a p-n junction between the second reference region and the specific region 69a at the position with the depth of 1 nm from the surface of the semiconductor substrate 60 is longer than or equal to 50 nm, for example.

A straight line that extends perpendicularly to the surface of the semiconductor substrate 60 will be defined as a perpendicular straight line. The perpendicular straight line can be a straight line that includes the a-a′ line in FIG. 12A.

The perpendicular straight line passes through a point that belongs to the specific region 69a and a point that belongs to the element isolation region 69b. A concentration of the impurity of the second conductivity type at the point that belongs to the specific region 69a is higher than a concentration of the impurity of the first conductivity type at the point that belongs to the element isolation region 69b.

The point that belongs to the specific region 69a can be a point where the concentration of the impurity of the second conductivity type reaches a maximum in the specific region 69a. The point that belongs to the element isolation region 69b can be a point where the concentration of the impurity of the first conductivity type reaches a maximum in the element isolation region 69b. Both of these characteristics may hold true or only one of the characteristics may hold true. In other words, the point where the concentration of the impurity of the second conductivity type reaches the maximum in the specific region 69a and the point where the concentration of the impurity of the first conductivity type reaches the maximum in the element isolation region 69b may be present on the same straight line that extends perpendicularly to the surface of the semiconductor substrate 60, or may not be present on the same straight line.

According to the above-described characteristics, the depletion layer originating from the p-n junction between the specific region 69a and the element isolation region 69b is likely to spread more toward the element isolation region 69b side than toward the specific region 69a side as understood from the explanations with reference to FIGS. 12A, 12B, 16A, and 16B. For this reason, according to the above-described characteristics, it is possible to reduce the depletion layer in the vicinity of the surface of the semiconductor substrate 60. Thus, it is possible to suppress the leakage current between the first impurity region and the second impurity region.

The specific region 69a may include a portion having the concentration of the impurity of the second conductivity type greater than or equal to 1×10¹⁹ cm⁻³. According to this characteristic, the specific region 69a is more likely to contribute to suppression of the leakage current between the first impurity region and the second impurity region.

Here, at the portion in the specific region 69a where the concentration of the impurity of the second conductivity type is the highest, the concentration of the impurity of the second conductivity type is smaller than or equal to 1×10²⁰ cm⁻³, for example. In one specific example, the concentration of the impurity of the second conductivity type is smaller than or equal to 5×10¹⁹ cm⁻³.

A straight line that extends parallel to the surface of the semiconductor substrate 60 will be defined as a parallel straight line. The parallel straight line passes through a point that belongs to the specific region 69a, a point that belongs to the reference region RA, and a point that belongs to the first impurity region in this order. To be more precise, the parallel straight line can be a straight light that extends at the position with the depth of 1 nm from the surface of the semiconductor substrate 60. The parallel straight line can be a straight line that includes the b-b′ lines in FIGS. 13A, 14A, 15A, and 16A.

A concentration of the impurity of the second conductivity type at the point that belongs to the specific region 69a is higher than a concentration of the impurity of the first conductivity type at the point that belongs to the reference region RA. According to this characteristic, the depletion layer originating from a p-n junction between the specific region 69a and the reference region RA spreads more toward the reference region RA side than toward the specific region 69a side as understood from the explanations with reference to FIGS. 13A to 16B. For this reason, according to the above-described characteristic, it is possible to suppress the leakage current between the first impurity region and the second impurity region.

The point that belongs to the specific region 69a can be a point of the portion of the specific region 69a at the depth of 1 nm from the surface of the semiconductor substrate 60, where the concentration of the impurity of the second conductivity type reaches a maximum. The point that belongs to the first impurity region can be a point of the portion of the first impurity region at the depth of 1 nm from the surface of the semiconductor substrate 60, where the concentration of the impurity of the second conductivity type reaches a maximum. The point that belongs to the reference region RA can be a portion on the parallel straight line in the reference region RA, where the concentration of the impurity of the first conductivity type reaches a maximum.

A proportion of the concentration of the impurity of the second conductivity type at the point that belongs to the specific region 69a to the concentration of the impurity of the first conductivity type at the point that belongs to the reference region RA is greater than or equal to 200, for example. This proportion may be greater than or equal to 1000. This proportion is smaller than or equal to 50000, for example.

The concentration of the impurity of the second conductivity type at the point that belongs to the first impurity region is higher than the concentration of the impurity of the first conductivity type at the point that belongs to the reference region RA. According to this characteristic, the depletion layer originating from the p-n junction between the first impurity region and the reference region RA is likely to spread more toward the reference region RA side than toward the first impurity region side as understood from the explanations with reference to FIGS. 13A to 16B. For this reason, according to the above-described characteristics, it is possible to suppress the leakage current between the first impurity region and the second impurity region.

A proportion of the concentration of the impurity of the second conductivity type at the point that belongs to the first impurity region to the concentration of the impurity of the first conductivity type at the point that belongs to the reference region RA is greater than or equal to 10000, for example. This proportion may be greater than or equal to 100000. This proportion is smaller than or equal to 600000, for example.

The concentration of the impurity of the second conductivity type at the point that belongs to the first impurity region is higher than the concentration of the impurity of the second conductivity type at the point that belongs to the specific region 69a. When the first impurity region is the charge accumulation region FD, the high concentration of the impurity in the first impurity region is advantageous from the viewpoint of ensuring a dynamic range of the imaging device 100. Moreover, this aspect is advantageous from the viewpoint of realizing a high-speed operation of the imaging device 100. Meanwhile, by suppressing the concentration of the impurity of the second conductivity type in the specific region 69a to an appropriate level, it is possible to ensure reliability of operations of the transistors and the like while suppressing an increase in the size of the imaging device 100.

A proportion of the concentration of the impurity of the second conductivity type at the point that belongs to the first impurity region to the concentration of the impurity of the second conductivity type at the point that belongs to the specific region 69a is greater than or equal to 10, for example. This proportion may be greater than or equal to 20. This proportion is smaller than or equal to 60, for example.

An insulating layer is disposed on the surface of the semiconductor substrate 60. The specific region 69a is typically in contact with this insulating layer. Specifically, a material of the insulating layer is an oxide of the material of the semiconductor substrate 60. To be more precise, the material of the insulating layer is silicon oxide and the material of the semiconductor substrate 60 is silicon.

The charges in the element isolation region 69b can be thermally excited from the valence band Ev to the conductive band Ec through the interface state between the semiconductor substrate 60 and the insulating layer. However, as understood from the explanations with reference to FIGS. 16A and 16B, the level of the valence band of the element isolation region 69b is significantly away from the interface state on the surface of the semiconductor substrate 60 due to the presence of the specific region 69a. For this reason, the charges in the element isolation region 69b are less likely to be thermally excited from the valence band Ev to the conductive band Ec through the interface state. As a consequence, it is possible to suppress the leakage current between the first impurity region and the second impurity region. Here, the insulating layer can be the fifth insulating layer 75.

The first impurity region is typically in contact with the insulating layer. The second impurity region is in contact with the insulating layer.

The first contact plug Cp1 contains a prescribed impurity of the second conductivity type. The first impurity region includes a predetermined region. The predetermined region is coupled to the first contact plug Cp1. The predetermined region contains the prescribed impurity as the impurity of the second conductivity type.

The predetermined region can be obtained by diffusing the prescribed impurity in the first contact plug Cp1 into a portion corresponding to the predetermined region. According to this diffusion process, the predetermined region having a high impurity concentration can be realized. That is to say, according to this configuration, it is possible to obtain the predetermined region having the high impurity concentration. Moreover, the high impurity concentration of the predetermined region is advantageous from the viewpoint of suppressing intrusion of the depletion layer into the predetermined region. Meanwhile, according to this configuration, the first contact plug Cp1 can be appropriately coupled to the semiconductor substrate 60. Here, the predetermined region can be the second region 67b of the n-type impurity region 67n. The prescribed impurity can be phosphorus.

The first contact plug Cp1 is coupled to the predetermined region through the first contact hole h1. The second contact plug Cp2 is coupled to the second impurity region through the second contact hole h2. A p-n junction is formed between the predetermined region and the reference region RA. The first contact hole h1, the p-n junction, the element isolation region 69b, and the second contact hole h2 are arranged on a straight line in plan view.

As described above, the predetermined region can be provided with the high impurity concentration originating from the diffusion from the first contact plug Cp1. For this reason, according to the above-described characteristics, it is easier to set the impurity concentration of the predetermined region higher than the impurity concentration of the reference region RA. When the above-described magnitude relation holds true, the depletion layer originating from the p-n junction between the predetermined region and the reference region RA is likely to spread more toward the reference region RA side than toward the predetermined region side. As a consequence, according to the above-described characteristics, it is possible to suppress the leakage current between the first impurity region and the second impurity region.

A description will be given of the expression “the first contact hole h1, the p-n junction, the element isolation region 69b, and the second contact hole h2 are arranged on a straight line in plan view” in the above-mentioned context. To be more precise, this expression means that there is the straight line that passes through the first contact hole h1, the p-n junction, the element isolation region 69b, and the second contact hole h2 in this order in plan view. In the example of FIG. 11B, the p-n junction can be the p-n junction 67bpn. The straight line can be a chain line DL.

The specific region 69a contains phosphorus as the impurity of the second conductivity type. Phosphorus has a high solid solution limit concentration relative to the typical semiconductor substrate 60. For example, phosphorus has a high solid solution limit concentration relative to a silicon substrate. For this reason, according to the configuration in which the specific region 69a contains phosphorus as the impurity, it is possible to realize the specific region 69a having the high impurity concentration. As a consequence, according to this configuration, it is easy to obtain the state where the depletion layer does not spread into the specific region 69a or the state where the spread of the depletion layer remains within a small range in the specific region 69a. Thus, a leakage current between the first impurity region and the second impurity region is suppressed easily.

The first contact plug Cp1 is coupled to the first impurity region through the first contact hole h1. A distance between an end portion of the first contact hole h1 and the end portion of the specific region 69a is longer than or equal to 50 nm and shorter than or equal to 500 nm in plan view. As understood from the explanations with reference to FIGS. 11A, 12A, and 17, this characteristic is suitable for suppressing the leakage current between the first impurity region and the second impurity region. In the above-mentioned context, the end portion of the specific region 69a indicates the p-n junction between the specific region 69a and the reference region RA. The distance may be longer than or equal to 50 nm and shorter than or equal to 300 nm.

The p-n junction is formed between the specific region 69a and the element isolation region 69b. In the perpendicular direction being perpendicular to the surface of the semiconductor substrate 60, a distance between this p-n junction and the surface of the semiconductor substrate 60 is longer than or equal to 5 nm and shorter than or equal to 30 nm, for example. This distance may be longer than or equal to 10 nm and shorter than or equal to 20 nm.

The first contact plug Cp1 may be a silicide. In this case, however, the metal is introduced into the first contact plug Cp1 in the process to form the first contact plug Cp1 into the silicide. All of the metal introduced in this process does not always contribute to formation of the first contact plug Cp1 into the silicide. The portion of the metal that does not contribute to the formation of the silicide may cause a trap level. The charges in the semiconductor substrate 60 may be thermally excited from the valence band Ev to the conductive band Ec through the trap level. As a consequence, the trap level may increase the leakage current between the first impurity region and the second impurity region.

In view of the above, an example where the first contact plug Cp1 is a non-silicide can be adopted. In this example, the first impurity region is in contact with the first contact plug Cp1. This example does not require the process to form the first contact plug Cp1 into the silicide. Accordingly, a problem of causing the trap level by the metal is less likely to occur. As a consequence, the leakage current between the first impurity region and the second impurity region originating from the trap level can be suppressed. To be more precise, since the specific region 69a is present in this example as described above, the charges in the element isolation region 69b are less likely to be thermally excited from the valence band Ev to the conductive band Ec through the interface state on the surface of the semiconductor substrate 60. Accordingly, the thermal excitation through the trap level or the thermal excitation through the interface level is less likely to occur. A synergic action of these aspects can suppress the leakage current between the first impurity region and the second impurity region.

Here, each of the contact plugs Cp2 to Cp1 may be either a silicide or a non-silicide.

The imaging device 100 according to one example includes the pixel region R1 and the peripheral region R2. At least one pixel 10 is provided in the pixel region R1. The peripheral circuits 40 are provided in the peripheral region R2. The peripheral circuits 40 controls the pixel 10. To be more precise, the peripheral circuits 40 control the transistors such as the signal detection transistor 22. The pixel region R1 includes the first impurity region, the second impurity region, the element isolation region 69b, and the specific region 69a. The element isolation region 69b is the implanted isolation region. The peripheral region R2 includes a shallow trench isolation (STI) structure. The STI is typically formed by using a silicon oxide. The single pixel 10 can be provided with the first impurity region, the second impurity region, the element isolation region 69b, and the specific region 69a.

As compared to the STI, the implanted isolation region can easily reduce a density of the interface state that functions as the center of generation and recombination of the charges. For this reason, the use of the implanted isolation region as the element isolation region is advantageous in light of suppressing the spread of the depletion layer in the vicinity of the surface of the semiconductor substrate 60 and suppressing the leakage current. Meanwhile, a width of the STI can be reduced more easily than a width of the implanted isolation region. For this reason, the use of the STI as the element isolation region is advantageous in light of reducing the size of a region to be provided with the element isolation region. From the viewpoint of obtaining an image at high image quality, reduction in leakage current may typically be of more importance in the pixel region R1. On the other hand, reduction in leakage current is less important in the peripheral region R2 than in the pixel region R1, and reduction in size may be of more importance in the peripheral region R2. In consideration of the above-mentioned performances required in the pixel region R1 and the peripheral region R2, it is reasonable to adopt a configuration to form the element isolation region 69b into the implanted isolation region and to provide the peripheral region R2 with the STI.

The “first impurity region” can be translated into the “second impurity region”, and the “second impurity region” can be translated into the “first impurity region”.

The imaging device and the method of manufacturing the imaging device according to the present disclosure have been described above. It is to be noted, however, that the present disclosure is not limited only to the above-described embodiment. Various modified modes that the persons skilled in the art can think of, other modes constructed by a combination of some of the constituents in the above-described embodiment, and the like are also encompassed by the scope of the present disclosure.

In the example of FIG. 4, for instance, the shield structure 69 formed as a combination of the element isolation region 69b and the specific region 69a surrounds the sources and the drains of the respective transistors in the pixel 10A. Instead, the shield structure 69 may be locally provided between the first impurity region and the second impurity region. For example, the shield structure 69 may be locally provided between the charge accumulation region FD and the n-type impurity region 68bn.

The area of the depletion layer can be reduced by the techniques according to the present disclosure. As a consequence, it is possible to reduce the leakage current and thus to perform imaging at high image quality. For example, the imaging device of the present disclosure is useful for a digital camera and the like. To be more precise, the imaging device of the present disclosure is applicable, for example, to a camera for medical use, a camera for a robot, a security camera, camera mounted on and used in a vehicle, and so forth.

What is claimed is:

1. An imaging device comprising:
a semiconductor substrate including
a reference region,
a first impurity region,
a second impurity region,
an element isolation region, and
a specific region, wherein
the reference region contains an impurity of a first conductivity type,
each of the first impurity region and the second impurity region is located in the reference region and contains an impurity of a second conductivity type,
the element isolation region is located between the first impurity region and the second impurity region in plan view, and contains an impurity of the first conductivity type, and
the specific region is located between a surface of the semiconductor substrate and the element isolation region in a direction perpendicular to the surface, and contains an impurity of the second conductivity type.

2. The imaging device according to claim 1, wherein the first impurity region is a charge accumulation region that accumulates charges generated by photoelectric conversion.

3. The imaging device according to claim 1, further comprising:
a transistor including a source and a drain, wherein
the second impurity region is one of the source and the drain.

4. The imaging device according to claim 1, wherein
a concentration of the impurity of the second conductivity type at a first point that belongs to the specific region is higher than a concentration of the impurity of the first conductivity type at a second point that belongs to the element isolation region, and
an imaginary straight line that passes through the first point and the second point is perpendicular to the surface.

5. The imaging device according to claim 1, wherein the specific region includes a part in which a concentration of the impurity of the second conductivity type is greater than or equal to 1×10¹⁹ cm⁻³.

6. The imaging device according to claim 1, wherein
a concentration of the impurity of the second conductivity type at a third point that belongs to the specific region is higher than a concentration of the impurity of the first conductivity type at a fourth point that belongs to the reference region, and
an imaginary straight line that passes through the third point, the fourth point, and a fifth point that belongs to the first impurity region in an enumerated order is parallel to the surface.

7. The imaging device according to claim 1, wherein
a concentration of the impurity of the second conductivity type at a fifth point that belongs to the first impurity region is higher than a concentration of the impurity of the first conductivity type at a fourth point that belongs to the reference region, and
an imaginary straight line that passes through a third point that belongs to the specific region, the fourth point, and the fifth point in an enumerated order is parallel to the surface.

8. The imaging device according to claim 1, further comprising:
an insulating layer disposed on the surface, wherein
the specific region is in contact with the insulating layer.

9. The imaging device according to claim 1, further comprising:
a first contact plug that contains a prescribed impurity of the second conductivity type, wherein
the first impurity region includes a predetermined region, and
the predetermined region is coupled to the first contact plug and contains the prescribed impurity as the impurity of the second conductivity type.

10. The imaging device according to claim 9, further comprising:
a first contact hole;
a second contact plug; and
a second contact hole, wherein
the first contact plug is coupled to the predetermined region through the first contact hole,
the second contact plug is coupled to the second impurity region through the second contact hole,
a p-n junction is formed between the predetermined region and the reference region, and
the first contact hole, the p-n junction, the element isolation region, and the second contact hole are arranged in an enumerated order on a straight line in plan view.

11. The imaging device according to claim 1, wherein the specific region contains phosphorus as the impurity of the second conductivity type.

12. The imaging device according to claim 1, further comprising:
a first contact plug; and
a first contact hole, wherein
the first contact plug is coupled to the first impurity region through the first contact hole, and
a distance between an end portion of the first contact hole and an end portion of the specific region is longer than or equal to 50 nm and shorter than or equal to 500 nm in plan view.

13. The imaging device according to claim 1, further comprising:
a pixel region provided with at least one pixel; and
a peripheral region provided with a peripheral circuit that controls the at least one pixel, wherein
the pixel region includes the first impurity region, the second impurity region, the element isolation region, and the specific region,
the element isolation region is an implanted isolation region, and
the peripheral region includes a shallow trench isolation structure.

14. The imaging device according to claim 1, wherein
the reference region is disposed between the second impurity region and the specific region in plan view.

15. The imaging device according to claim 1, further comprising:
a plurality of pixels, wherein
each of the pixels includes the reference region, the first impurity region, the second impurity region, the element isolation region, and the specific region.

16. The imaging device according to claim 1, wherein the reference region is located between the first impurity region and the specific region.

17. The imaging device according to claim 1, wherein each of the first impurity region and the second impurity region is not in contact with the specific region.

18. The imaging device according to claim 1, wherein the specific region does not contain an impurity of the first conductivity type.

19. The imaging device according to claim 1, wherein
the specific region is in contact with the surface of the semiconductor substrate, and
the element isolation region is not in contact with the surface of the semiconductor substrate.

20. The imaging device according to claim 1, wherein
a p-n junction is formed between the specific region and the element isolation region, and
a distance between the surface of the semiconductor substrate and the p-n junction in the direction perpendicular to the surface is longer than or equal to 5 nm and shorter than or equal to 30 nm.
